(19) United States
(12) Patent Application Publication
(10) Pub. No.: US 2025/0301644 A1
(43) Pub. Date: Sep. 25, 2025

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventor: Juhyung KIM, Suwon-si (KR)

(73) Assignee: SAMSUNG ELECTRONICS CO., LTD., Suwon-si (KR)

(21) Appl. No.: 18/826,517

(22) Filed: Sep. 6, 2024

(30) Foreign Application Priority Data
Mar. 21, 2024 (KR) 10-2024-0039287

(51) Int. Cl. H10B 43/27; H01L 25/065; H10B 43/10; H10B 43/35; H10B 51/10; H10B 51/20; H10B 80/00

(52) U.S. Cl. CPC H10B 43/27; H01L 25/0652; H10B 43/10; H10B 43/35; H10B 51/10; H10B 51/20; H10B 80/00; H01L 2225/06506

(57) ABSTRACT

A semiconductor device according to an embodiment includes a gate stacking structure, a channel layer, a ferroelectric layer, and a conductive structure. The gate stacking structure includes a plurality of gate electrodes and a plurality of cell insulation layers alternately stacked with each other. The channel layer extends in an extension direction to pass through the gate stacking structure. The conductive structure is disposed between the ferroelectric layer and the channel layer to partially overlap one of the plurality of gate electrodes in a direction perpendicular to the extension direction. An electronic system includes such a semiconductor device.

### CROSS-REFERENCE TO RELATED APPLICATION

This application claims priority to and the benefit of Korean Patent Application No. 10-2024-0039287 filed in the Korean Intellectual Property Office on Mar. 21, 2024, the entire contents of which are incorporated herein by reference.

### BACKGROUND

### (a) Field

The present disclosure relates to a semiconductor device and an electronic system including the same. More particularly, the present disclosure relates to a semiconductor device having an enhanced structure and an electronic system including the same.

### (b) Description of the Related Art

In an electronic system implementing a data storage, a semiconductor device capable of storing high-capacity data is in demand. Accordingly, a method for increasing a data storage capacity of a semiconductor device is being researched. For example, as one method for increasing the data storage capacity of a semiconductor device, a semiconductor device including three-dimensionally arranged memory cells instead of two-dimensionally arranged memory cells has been proposed.

### SUMMARY

The present disclosure attempts to provide a semiconductor device capable of enhancing performance and reliability, and an electronic system including the same.

A semiconductor device according to an embodiment includes a gate stacking structure, a channel layer, a ferroelectric layer, and a conductive structure, and a channel structure. The gate stacking structure includes a plurality of gate electrodes and a plurality of cell insulation layers alternately stacked with each other. The channel layer extends in an extension direction to pass through the gate stacking structure. The conductive structure is disposed between the ferroelectric layer and the channel layer to partially overlap one of the plurality of gate electrodes in a direction perpendicular to the extension direction.

A semiconductor device according to an embodiment includes a gate stacking structure and a channel structure. The gate stacking structure includes a plurality of gate electrodes and a plurality of cell insulation layers alternately stacked with each other. The channel structure extends to pass through the gate stacking structure. The channel structure includes a channel layer and a plurality of separated stacking portions that are disposed between the channel layer and the plurality of gate electrodes, respectively. At least one of the plurality of separated stacking portions includes a ferroelectric layer and a conductive structure. The plurality of separated stacking portions have a separated structure that is separated to correspond to the plurality of gate electrodes, respectively. The at least one of the plurality of separated stacking portions has a recess portion disposed inside one of the plurality of gate electrodes in an extension direction of the channel structure.

An electronic system according to an embodiment includes a main substrate, a semiconductor device on the main substrate, and a controller that is disposed on the main substrate and is electrically connected to the semiconductor device. The semiconductor device includes a gate stacking structure, a channel layer, a ferroelectric layer, and a conductive structure. The gate stacking structure includes a plurality of gate electrodes and a plurality of cell insulation layers alternately stacked with each other. The channel layer extends in an extension direction to pass through the gate stacking structure. The conductive structure is disposed between the ferroelectric layer and the channel layer to partially overlap one of the plurality of gate electrodes in a direction perpendicular to the extension direction.

According to an embodiment, in a semiconductor device (e.g., a ferroelectric memory device) that includes a ferroelectric layer, polarization charges may be sufficiently compensated by a conductive pattern that is adjacent to the ferroelectric layer, and thus, depolarization may be suppressed. Accordingly, disturbance that may occur due to the depolarization may be preventer and retention may be enhanced. Accordingly, performance and reliability of the semiconductor device may be enhanced.

### BRIEF DESCRIPTION OF THE DRAWINGS

FIG. 1 is a partial cross-sectional view that schematically illustrates a semiconductor device according to an embodiment.

FIG. 2 is an enlarged partial cross-sectional view that illustrates an example of a channel structure included in the semiconductor device illustrated in FIG. 1.

FIG. 3 is a partial cross-sectional view that illustrates a partial portion of a memory cell structure included in the semiconductor device illustrated in FIG. 1.

FIG. 4 is a partial plan view that illustrates a partial portion of the memory cell structure included in the semiconductor device illustrated in FIG. 1.

FIG. 5A conceptually illustrates a charge distribution in a gate electrode and the channel structure that are included in the semiconductor device illustrated in FIG. 1 when a ferroelectric layer is in a first polarization state. FIG. 5B conceptually illustrates a charge distribution in a comparative example in which a conductive pattern is not included.

FIG. 6 is a partial cross-sectional view that illustrates a partial portion of a memory cell structure included in a semiconductor device according to an embodiment.

FIG. 7 is a partial cross-sectional view that illustrates a partial portion of a memory cell structure included in a semiconductor device according to an embodiment.

FIG. 8 is a partial cross-sectional view that illustrates a partial portion of a memory cell structure included in a semiconductor device according to an embodiment.

FIG. 9 is a partial cross-sectional view that illustrates a partial portion of a memory cell structure included in a semiconductor device according to a modified embodiment.

FIG. 10 conceptually illustrates a charge distribution in a gate electrode and a channel structure that are included in the semiconductor device illustrated in FIG. 8 when a ferroelectric layer is in a first polarization state.

FIG. 11 to FIG. 15 are cross-sectional views that illustrate a manufacturing method of a semiconductor device according to an embodiment.

FIG. 16 is a partial cross-sectional view that illustrates a partial portion of a memory cell structure included in a semiconductor device according to an embodiment.

FIG. 17 is a partial cross-sectional view that illustrates a partial portion of a memory cell structure included in a semiconductor device according to an embodiment.

FIG. 18 is a cross-sectional view that schematically illustrates a semiconductor device according to an embodiment.

FIG. 19 schematically illustrates an electronic system that includes a semiconductor device according to an embodiment.

FIG. 20 is a perspective view that schematically illustrates an electronic system including a semiconductor device according to an embodiment.

FIG. 21 is a cross-sectional view that schematically illustrates a semiconductor package according to an embodiment.

FIG. 22 is a cross-sectional view that schematically illustrates a semiconductor package according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiment provided herein.

A portion unrelated to the description is omitted in order to clearly describe the present disclosure, and the same or similar components are denoted by the same reference numeral throughout the present specification.

Further, since a size and/or a thickness of a portion, a region, a member, a unit, a layer, a film, a substrate, or so on illustrated in the accompanying drawings may be arbitrarily illustrated for better understanding and convenience of explanation, the present disclosure is not limited to the illustrated size and/or thickness. In the drawings, thicknesses of portions, regions, members, units, layers, films, etc. may be enlarged or exaggerated for convenience of explanation and/or simple illustration.

It will be understood that when a component such as a portion, a region, a member, a unit, a layer, a film, a substrate, or so on is referred to as being “on” another component, it may be directly on another component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate when a cross-section taken along a vertical direction is viewed from a side.

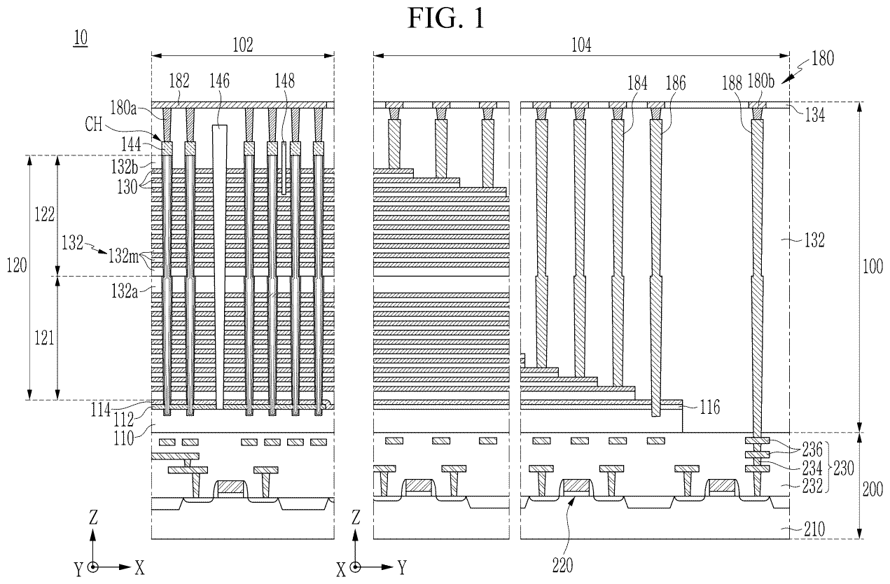

Hereinafter, with reference to FIG. 1 to FIG. 5B, a semiconductor device 10 according to an embodiment will be described in detail.

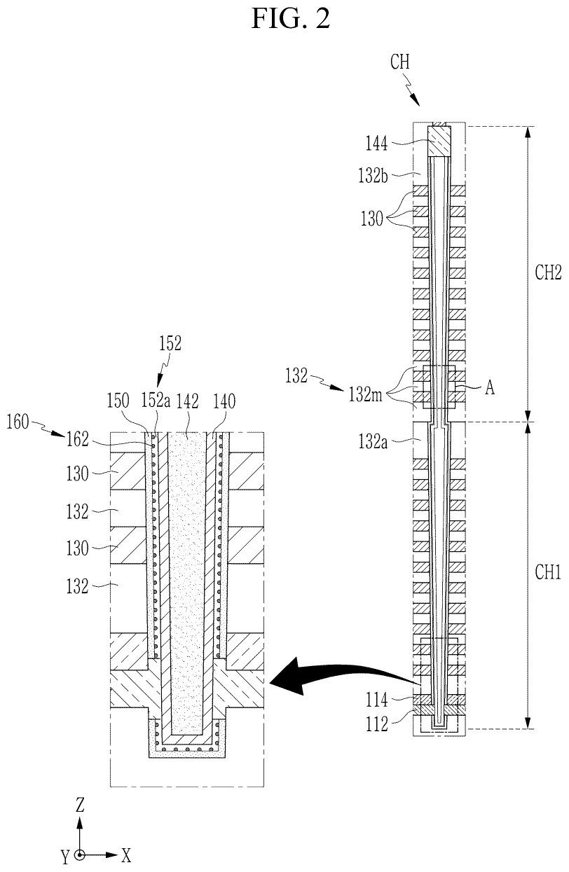

FIG. 1 is a partial cross-sectional view that schematically illustrates a semiconductor device 10 according to an embodiment. FIG. 2 is an enlarged partial cross-sectional view that illustrates an example of a channel structure CH included in the semiconductor device 10 illustrated in FIG. 1. For a clear understanding, coordinates of FIG. 1 are illustrated based on a cell array region 100, and a circuit region 200 is schematically illustrated regardless of coordinates. For a clear understanding, a gate contact portion 184, a source contact portion 186, and an input/output connection wiring 188 are illustrated together in FIG. 1, but positions of the gate contact portion 184, the source contact portion 186, and the input/output connection wiring 188 may be variously modified.

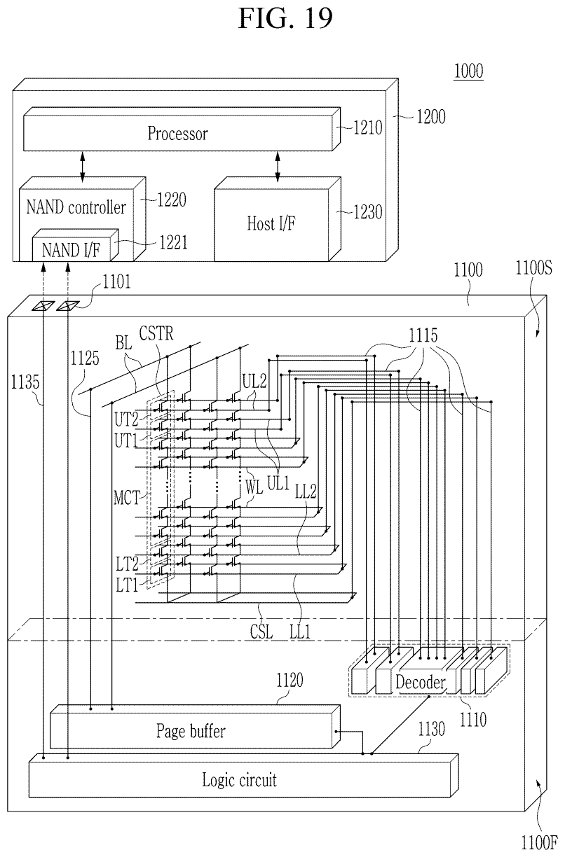

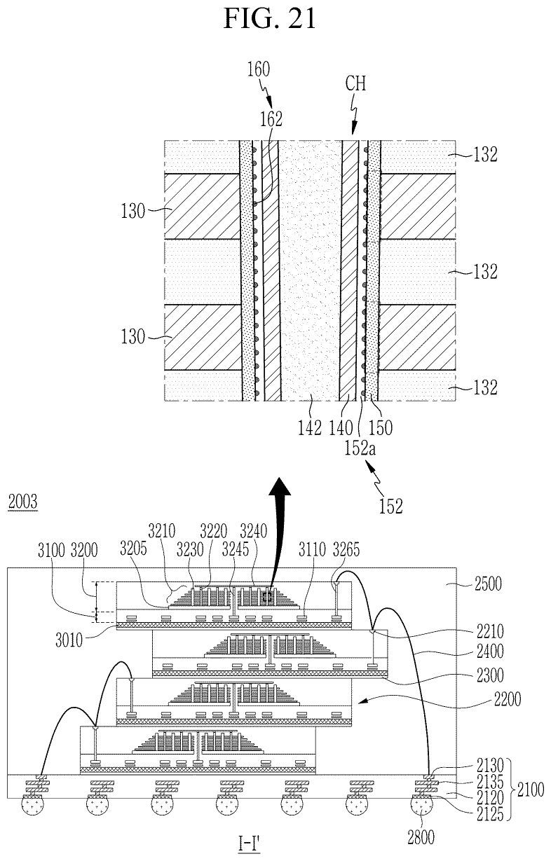

Referring to FIG. 1 and FIG. 2, a semiconductor device 10 according to an embodiment may include a cell region 100 that includes a memory cell structure and a circuit region 200 that includes a peripheral circuit structure for controlling an operation of the memory cell structure. For example, the circuit region 200 and the cell region 100 may correspond to a first structure 1100F and a second structure 1100S of a semiconductor device 1100 that is included in an electronic system 1000 illustrated in FIG. 19, respectively. For example, the circuit region 200 and the cell region 100 may be portions that include a first structure 3100 and a second structure 3200 of a semiconductor chip 2200 illustrated in FIG. 21, respectively.

In an embodiment, the cell region 100 may be disposed on the circuit region 200. Accordingly, an area corresponding to the circuit region 200 does not need to be secured separately from the cell region 100. Therefore, an area of the semiconductor device 10 may be reduced. However, the embodiments are not limited thereto. The circuit region 200 may be next to the cell region 100. Other various modifications are possible.

The circuit region 200 may include a first substrate 210, and a circuit element 220 and a first wiring portion 230 that are disposed on the first substrate 210.

The first substrate 210 may be a semiconductor substrate that includes a semiconductor material. For example, the first substrate 210 may be a semiconductor substrate that includes or is formed of a semiconductor material or may be a semiconductor substrate in which a semiconductor layer is on a base substrate. For example, the first substrate 210 may include single-crystalline or polycrystalline silicon, epitaxial silicon, germanium, silicon-germanium, silicon on insulator (SOI), germanium on insulator (GOI), or so on.

The circuit element 220 that is disposed on the first substrate 210 may include any of various circuit elements. For example, the circuit element 220 may constitute the peripheral circuit structure such as a decoder circuit 1110 (refer to FIG. 19), a page buffer 1120 (refer to FIG. 19), a logic circuit 1130 (refer to FIG. 19), or so on.

The circuit element 220 may include a transistor, but the embodiments are not limited thereto. For example, the circuit element 220 may include not only an active element such as the transistor or so on but also a passive element such as a capacitor, a resistor, an inductor, or so on.

The first wiring portion 230 that is disposed on the first substrate 210 may be electrically connected to the circuit element 220. In an embodiment, the first wiring portion 230 may include a plurality of wiring layers 236 that are spaced apart from each other while interposing an insulation layer 232 therebetween and are electrically connected by a contact via 234 to form a desired path. The wiring layer 236 or the contact via 234 may include or be formed of any of various conductive materials, and the insulation layer 232 may include or be formed of any of various insulating materials. For example, among the plurality of wiring layers 236, an uppermost wiring layer 236 may include or constitute a pad to which a gate contact portion 184, a source contact portion 186, an input/output connection wiring 188, or so on is connected.

The cell region 100 may include a cell array region 102 and a connection region 104. The cell region 100 may include a gate stacking structure 120 and a channel structure CH as the memory cell structure. The gate stacking structure 120 and/or the channel structure CH may be disposed at least in the cell array region 102. A structure that connects the memory cell structure to the circuit region 200 or an external circuit may be disposed in the cell array region 102 and/or the connection region 104.

In an embodiment, the second substrate 110 may include a semiconductor layer including a semiconductor material. For example, the second substrate 110 may be a semiconductor substrate that includes or is formed of a semiconductor material or may be a semiconductor substrate in which a semiconductor layer is on a base substrate. For example, the second substrate 110 may include or be formed of silicon, germanium, silicon-germanium, silicon on insulator, germanium on insulator, or so on. In this instance, the second substrate 110 may include an n-type semiconductor layer that includes an n-type dopant (such as phosphorus (P), arsenic (As), or so on) and/or a p-type semiconductor layer that includes a p-type dopant (such as boron (B), gallium (Ga), or so on). However, the embodiments are not limited to a material of the second substrate 110, a conductive type, a material, or so on of the dopant doped to the semiconductor layer of the second substrate 110.

The gate stacking structure 120 may include a plurality of cell insulation layers 132 and a plurality of gate electrodes 130 that are alternately stacked on a first surface (e.g., a front surface or an upper surface) of the second substrate 110. The channel structure CH may extend in an extension direction that crosses the second substrate 110 and pass through the gate stacking structure 120. For example, the extension direction of the channel structure CH may be a direction that crosses the second substrate 110 (e.g., a vertical direction that is perpendicular to the second substrate 110) or may be a thickness direction of the semiconductor device 10. The extension direction of the channel structure CH may be a Z-axis direction in the drawing.

In an embodiment, horizontal conductive layers 112 and 114 may be provided between the second substrate 110 and the gate stacking structure 120 in the cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 that are sequentially on the second substrate 110. The first horizontal conductive layer 112 may act as a partial portion of a common source line of the semiconductor device 10. For example, the first horizontal conductive layer 112 may act as the common source line together with the second substrate 110.

The first and second horizontal conductive layers 112 and 114 may include a semiconductor material (e.g., polycrystalline silicon). For example, the first horizontal conductive layer 112 may include a polycrystalline silicon layer that includes a dopant. The embodiments are not limited thereto. The second horizontal conductive layer 114 may include a material (e.g., an insulating material) that is different from a material of the first horizontal conductive layer 112, or the second horizontal conductive layer 114 may be omitted.

The gate stacking structure 120 may be disposed on the second substrate 110 (e.g., on the first and second horizontal conductive layers 112 and 114 that are disposed on the second substrate 110). The gate stacking structure 120 may include the cell insulation layers 132 and the gate electrodes 130 alternately stacked with each other.

The cell insulation layer 132 may include an interlayer insulation layer 132m and an upper insulation layer 132a or 132b. The interlayer insulation layer 132m may be disposed between two gate electrodes 130 that are adjacent to each other in each of a plurality of gate stacking portions 121 and 122. The upper insulation layers 132a and 132b may be at upper surfaces of the plurality of gate stacking portions 121 and 122, respectively. In an embodiment, thicknesses of the plurality of cell insulation layers 132 might not be the same. For example, a thickness of the upper insulation layer 132a or 132b may be greater than a thickness of the interlayer insulation layer 132m. However, the embodiments are not limited thereto. For simple illustration, it is illustrated as an example in FIG. 1 that the cell insulation layer 132 is provided as one without a boundary in the connection region 104. However, one or a plurality of insulation layers may be disposed to have any of various stacking structures in the connection region 104. A shape, a structure, or so on of the cell insulation layer 132 may be variously modified in some embodiments.

The gate electrode 130 may include or be formed of any of various conductive materials. For example, the gate electrode 130 may include a metal material (e.g., tungsten (W), copper (Cu), aluminum (Al), molybdenum (Mo), or so on), polycrystalline silicon (e.g., doped polycrystalline silicon), metal nitride (e.g., titanium nitride (TiN), tantalum nitride (TaN), tungsten nitride (WN), or so on), or a combination thereof. The cell insulation layer 132 may include or be formed of any of various insulating materials. For example, the cell insulation layer 132 may include silicon oxide, silicon nitride, silicon oxynitride, a low dielectric constant material that has a lower dielectric constant than silicon oxide, or a combination thereof.

The channel structure CH may include a channel layer 140, and a stacking portion that is disposed between the channel layer 140 and the gate electrode 130. The stacking portion may include at least a ferroelectric layer 150 and a conductive pattern 160 as a conductive structure. The conductive pattern 160 may be referred to as a conductive structure. The channel structure CH may further include a core insulation layer 142 inside the channel layer 140. In some embodiments, the core insulation layer 142 may be omitted. The channel structure CH may further include a channel pad 144 that is electrically connected to the channel layer 140. The channel pad 144 may cover an upper surface of the core insulation layer 142 and be electrically connected to the channel layer 140.

Each channel structure CH may form one memory cell string, and a plurality of channel structures CH may be spaced apart from each other to form rows and columns in a plan view. The channel structure CH may have a pillar shape (e.g., a circular cylinder shape). For example, in a cross-sectional view, the channel structure CH may have an inclined side surface so that a width of the channel structure CH decreases as the channel structure CH goes to the second substrate 110 due to a high aspect ratio. However, the embodiments are not limited thereto, and an arrangement, a structure, a shape, or so on of the channel structure CH may be variously modified.

The channel layer 140 may include a semiconductor material (e.g., polycrystalline silicon). More particularly, the channel layer 140 may include or be formed of a doped or undoped semiconductor material (e.g., doped or undoped polycrystalline silicon). In some embodiments, the channel layer 140 may include or be formed of an oxide semiconductor material or a two-dimensional semiconductor material. For example, the channel layer 140 may include or be formed of zinc oxide (ZnOₓ), zinc oxynitride (ZnONₓ), tin oxide (SnOₓ), zinc tin oxide (ZTO), indium oxide (InOₓ), indium zinc oxide (IZO), indium gallium zinc oxide (IGZO), indium gallium silicon oxide (IGSO), titanium oxide (TiOX), or so on, or may include or be formed of a material that includes the above material and further includes a dopant. The dopant may include at least one of magnesium (Mg), zirconium (Zr), hafnium (Hf), tin (Sn), aluminum (Al), silicon (Si), or gallium (Ga). For example, the channel layer 140 may include or be formed of an n-type oxide semiconductor material, but the embodiments are not limited thereto. A material of the channel layer 140 may be variously modified.

The core insulation layer 142 may include or be formed of any of various insulating materials. For example, the core insulation layer 142 may include or be formed of silicon oxide, silicon nitride, silicon oxynitride, or a combination thereof. The channel pad 144 may be electrically connected to the channel layer 140. The channel pad 144 may include or be formed of a conductive material (e.g., polycrystalline or single-crystalline silicon doped with a dopant). However, the embodiments are not limited to a structure, a material, or so on of the channel layer 140, the core insulation layer 142, or the channel pad 144.

In an embodiment, the stacking portion that is disposed between the channel layer 140 and the gate electrode 130 may include the ferroelectric layer 150 and the conductive pattern 160, and may further include an interfacial insulation layer 152. More particularly, the conductive pattern 160 may be disposed between the ferroelectric layer 150 and the channel layer 140 on an inner surface 1501 of the ferroelectric layer 150 that is opposite to the gate electrodes 130. The interfacial insulation layer 152 may include a first interfacial insulation layer 152a that covers the conductive pattern 160 on the inner surface 1501 of the ferroelectric layer 150. The first interfacial insulation layer 152a may be disposed between a portion, which includes the ferroelectric layer 150 and the conductive pattern 160, and the channel layer 140.

The ferroelectric layer 150 may include or be formed of a ferroelectric (FE) material.

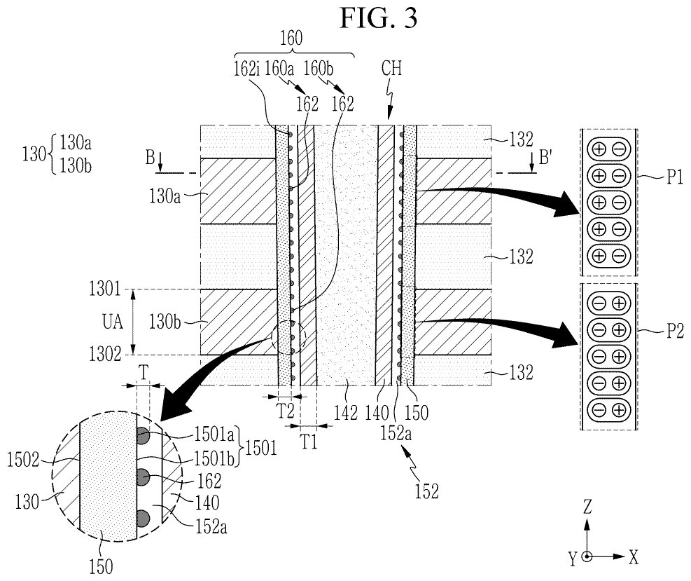

The ferroelectric material may maintain remnant polarization due to dipoles without an externally applied electric field and thus data may be stored in the ferroelectric material non-volatilely. A polarization direction in the ferroelectric material may be changed by an externally applied electric field. Data may be stored in the ferroelectric layer 160 by using the property of the ferroelectric layer 150. An operation method of the semiconductor device 10 (e.g., a ferroelectric memory device) that includes the memory cell structure with the ferroelectric layer 150 will be described later in detail with reference to FIG. 3.

In an embodiment, the ferroelectric layer 150 may include at least one of hafnium (Hf), zirconium (Zr), silicon (Si), yttrium (Y), aluminum (Al), gadolinium (Gd), strontium (Sr), lanthanum (La), titanium (Ti), or scandium (Sc), or an oxide including the above material. For example, the ferroelectric layer 150 may include a base material that includes at least one of hafnium oxide, zirconium oxide, or hafnium-zirconium oxide, and the ferroelectric layer 150 may include the base material and a dopant. In this instance, the dopant may include hafnium, zirconium, silicon, yttrium, aluminum, gadolinium, strontium, lanthanum, titanium, scandium, carbon (C), germanium (Ge), tin (Sn), lead (Pb), magnesium (Mg), calcium (Ca), barium (Ba), zinc (Zn), nitrogen (N), or tantalum (Ta), or a combination thereof. For example, the base material of the ferroelectric layer 150 may include or be formed of the hafnium oxide.

The embodiments are not limited to a material of the ferroelectric layer 150, and the ferroelectric layer 150 may include or be formed of any of various ferroelectric materials. In an embodiment, the ferroelectric layer 150 may include or be formed of a ferroelectric material that has a crystalline structure (e.g., a ferroelectric material that has an orthorhombic crystal structure or a perovskite structure). For example, the ferroelectric layer 150 may include or be formed of at least one of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, or BaSrTiO₃, or a combination thereof.

The interfacial insulation layer 152 may prevent undesirable charge or material transfer between the ferroelectric layer 150 and the channel layer 140. In an embodiment, the interfacial insulation layer 152 may include or be formed of silicon oxide (SiOₓ), silicon nitride (SiNₓ), silicon oxynitride (SiONₓ), aluminum oxide (AlOₓ), aluminum oxynitride (AlONₓ), hafnium oxide (HfO), a high dielectric constant material that has a higher dielectric constant than silicon oxide, or a combination thereof.

In an embodiment, a material, a stacking structure, a position or so on of the ferroelectric layer 150 or the interfacial insulation layer 152 may be variously modified, and the embodiments are not limited thereto.

The conductive pattern 160 will be described later in more detail with reference to FIG. 3 to FIG. 5B.

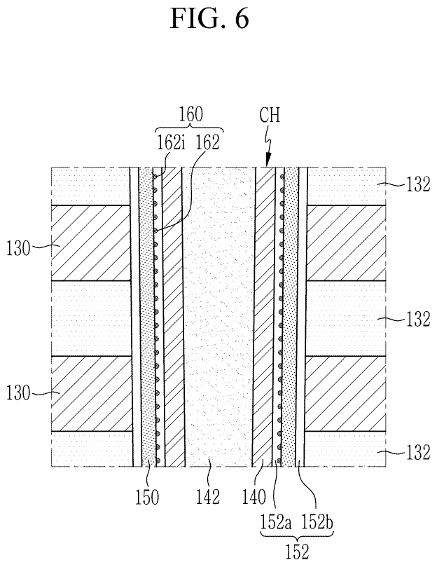

In the drawing, it is illustrated as an example that the interfacial insulation layer 152 includes a first interfacial insulation layer 152a that is disposed between the ferroelectric layer 150 and the channel layer 140. However, the interfacial insulation layer 152 may further include a second interfacial insulation layer 152b (refer to FIG. 6) or so on. The second interfacial insulation layer 152b will be described later in more detail with reference to FIG. 6.

In an embodiment, the gate stacking structure 120 may include a plurality of gate stacking portions 121 and 122 that are sequentially stacked on the second substrate 110. Thereby, a number of stacked gate electrodes 130 may be increased and thus a number of memory cells may be increased with a stable structure. Accordingly, a data storage capacity of the semiconductor device 10 may be increased. In FIG. 1, it is illustrated as an example that the gate stacking structure 120 includes first and second gate stacking portions 121 and 122. However, the embodiments are not limited thereto. In some embodiments, the gate stacking structure 120 may include one gate stacking portion or three or more gate stacking portions.

When the plurality of gate stacking portions 121 and 122 are provided as in the above, the channel structure CH may include a plurality of channel portions CH1 and CH2 that respectively pass through the plurality of gate stacking portions 121 and 122. The plurality of channel portions CH1 and CH2 may be connected to each other. In a cross-sectional view, each of the plurality of channel portions CH1 and CH2 may have an inclined side surface such that a width of each of the plurality of channel portions CH1 and CH2 decreases toward the second substrate 110 due to a high aspect ratio. A bent portion due to a difference in widths of the plurality of channel portions CH1 and CH2 may be provided at a connection portion of the plurality of channel structures CH1 and CH2. In some embodiments, the plurality of channel portions CH1 and CH2 may have an inclined side surface that continuously extends without the bent portion. In FIG. 2, it is illustrated as an example that the interfacial insulation layer 152, the ferroelectric layer 150, the channel layer 140, or the core insulation layer 142 of the plurality of channel portions CH1 and CH2 continuously extend to have an integral structure. In some embodiments, ferroelectric layers 150, channel layers 140, or core insulation layers 142 of the plurality of channel portions CH1 and CH2 may be separately formed and be electrically connected to each other. In some embodiments, a separate channel pad may be additionally disposed at the connection portion of the plurality of channel portions CH1 and CH2. The embodiments are not limited to a shape of the plurality of channel portions CH1 and CH2.

In an embodiment, the gate stacking structure 120 may be divided into a plurality of portions in a plan view by a separation structure 146. The separation structure 146 may extend in a direction (the Z-axis direction in the drawings) that crosses the second substrate 110 (e.g. the vertical direction perpendicular to the second substrate 110) to pass through the gate stacking structure 120. An upper separation region 148 may be at an upper portion of the gate stacking structure 120. In a plan view, the separation structure 146 and/or the upper separation region 148 may extend in a first direction (a Y-axis direction in the drawings) that is an extension direction of the gate electrode 130. A plurality of separation structures 146 and/or a plurality of upper separation regions 148 may be spaced apart from each other at a predetermined interval in a second direction (an X-axis direction in the drawings).

In a plan view, the plurality of gate stacking structures 120 may each extend in the first direction (the Y-axis direction of the drawing) and be spaced apart from each other at a predetermined interval in the second direction (the X-axis direction of the drawing) by the separation structure 146. The gate stacking structure 120 that is divided by the separation structure 146 may constitute one memory cell block. However, the embodiments are not limited thereto, and a range of the memory cell block is not limited thereto.

For example, the separation structure 146 may pass through the gate stacking structure 120 and extend to the second substrate 110, and the upper separation region 148 may separate one or a part of the plurality of gate electrodes 130. The upper separation region 148 may be disposed between the separation structures 146.

For example, in a cross-sectional view, the separation structure 146 may have an inclined side surface such that a width of the separation structure 146 gradually decreases toward the second substrate 110 due to a high aspect ratio. However, the embodiments are not limited thereto. A side surface of the separation structure 146 may be perpendicular to the second substrate 110, or the separation structure 146 may have a bent portion at the connection portion of the first and second gate stacking portions 121 and 122.

The separation structure 146 and/or the upper separation region 148 may include or be formed of any of various insulating materials. For example, the separation structure 146 or the upper separation region 148 may include or be formed of an insulating material such as silicon oxide, silicon nitride, or silicon oxynitride. However, the embodiments are not limited thereto, and a structure, a shape, a material, or so on of the separation structure 146 or the upper separation region 148 may be variously modified.

The connection region 104 and a second wiring portion 180 may be provided to connect the gate stacking structure 120 and the channel structure CH in the cell array region 102 to the circuit region 200 or an external circuit. The connection region 104 may be disposed at a periphery of the cell array region 102 and a partial portion of the second wiring portion 180 may be in the connection region 104.

In an embodiment, the second wiring portion 180 may include a member electrically connecting the gate electrode 130, the channel structure CH, the horizontal conductive layers 112 and 114, and/or the second substrate 110 to the circuit region 200 or the external circuit. For example, the second wiring portion 180 may include a bit line 182, a gate contact portion 184, a source contact portion 186, an input/output connection wiring 188, a contact via 180a, and a connection wiring 180b. The contact via 180a may be connected to the bit line 182, the gate contact portion 184, the source contact portion 186, and/or the input/output connection wiring 188. The connection wiring 180b may be electrically connected to the bit line 182, the gate contact portion 184, the source contact portion 186, the input/output connection wiring 188, and/or the contact via 180a.

The bit line 182 may extend in the second direction (the X-axis direction in the drawings) that is transverse to or crosses the first direction. The bit line 182 may be electrically connected to the channel structure CH (e.g., the channel pad 144) through the contact via 180a (e.g., a bit line contact via) that pass through the cell insulation layer 132.

In the connection region 104, the plurality of gate electrodes 130 may extend in the first direction (the Y-axis direction in the drawings). Extension lengths of the plurality of gate electrodes 130 may sequentially decrease in a direction away from the second substrate 110. For example, the plurality of gate electrodes 130 may have a stair shape in one direction or a plurality of directions in the connection region 104. In the connection region 104, a plurality of gate contact portions 184 may pass through the cell insulation layer 132 to be electrically connected to the plurality of gate electrodes 130, respectively, that extend to the connection region 104.

The source contact portion 186 may be electrically connected to the horizontal conductive layers 112 and 114 and/or the second substrate 110 that constitutes at least a partial portion of a common source line. The input/output connection wiring 188 may be electrically connected to an input/output pad.

The connection wiring 180b may be disposed in the cell array area 102 and/or the connection area 104. The bit line 182, the gate contact portion 184, the source contact portion 186, and/or the input/output connection wiring 188 may be electrically connected to the connection wiring 180b. For example, the gate contact portion 184, the source contact portion 186, and/or the input/output connection wiring 188 may be electrically connected to the connection wiring 180b through the contact via 180a.

In FIG. 1, it is illustrated as an example that the connection wiring 180b is a single layer on the same plane as the bit line 182 and an additional insulation layer 134 is a single layer on the same plane as the bit line 182 and the connection wiring 180b. However, this is brief illustration for convenience. For an electrical connection with the bit line 182, the gate contact portion 184, the source contact portion 186, and/or the input/output connection wiring 188, the connection wiring 180b may include a plurality of wiring layers and may further include a contact via.

By the second wiring portion 180 and the first wiring portion 230, the bit line 182 that is connected to the channel structure CH, the gate electrode 130, the horizontal conductive layers 112 and 114, and/or the second substrate 110 may be electrically connected to the circuit element 220 of the circuit region 200.

In FIG. 1, it is illustrated as an example that each of the gate contact portions 184, the source contact portion 186, and/or the input/output connection wiring 188 has an inclined side surface such that a width of each of the gate contact portion 184, the source contact portion 186, and/or the input/output connection wiring 188 decreases toward the second substrate 110 due to an aspect ratio and a bent portion is provided at a boundary portion of the plurality of gate stacking portions 121 and 122 in a cross-sectional view. However, the embodiments are not limited thereto. In some embodiments, the gate contact portion 184, the source contact portion 186, and/or the input/output connection wiring 188 might not include the bent portion at the boundary portion of the plurality of gate stacking portions 121 and 122. Other various modifications are possible.

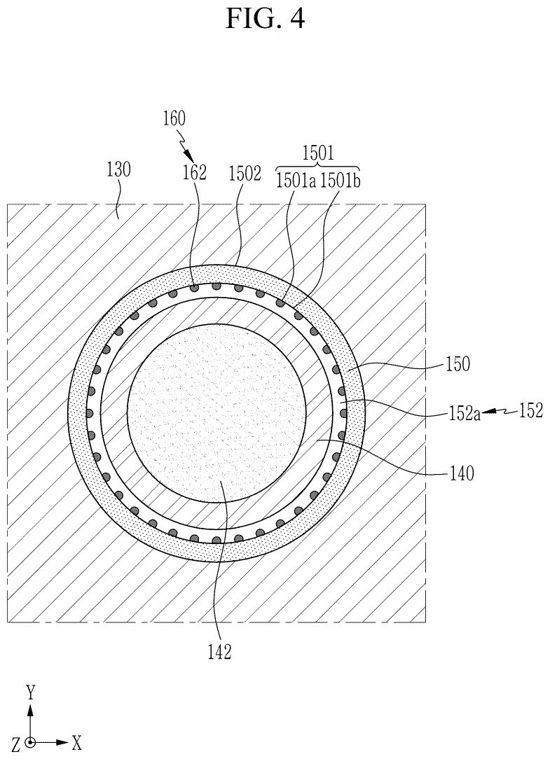

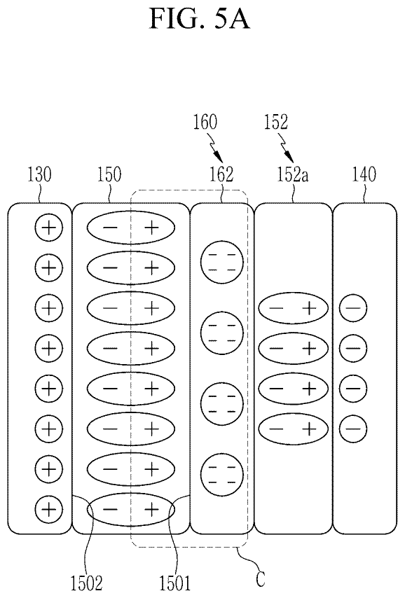

In an embodiment, in the channel structure CH, the conductive pattern 160 may be disposed on the inner surface 1501 of the ferroelectric layer 150 that is opposite to the gate electrode 130. This will be described in more detail with reference to FIG. 3 and FIG. 4 together with FIG. 1 and FIG. 2.

FIG. 3 is a partial cross-sectional view that illustrates a partial portion of the memory cell structure included in the semiconductor device 10 illustrated in FIG. 1. FIG. 4 is a partial plan view that illustrates a partial portion of the memory cell structure included in the semiconductor device 10 illustrated in FIG. 1. FIG. 3 illustrates a portion corresponding to a portion A in FIG. 2, and FIG. 4 illustrates a plan view taken along a line B-B′ in FIG. 3.

Referring FIG. 1 to FIG. 4, in an embodiment, the ferroelectric layer 150 may include an inner surface 1501 and an outer surface 1502. The inner surface 1501 and the outer surface 1502 may be disposed between the plurality of gate electrodes 130 and the channel layer 140 and be opposite to each other.

In a plan view, the gate electrode 130 may surround the channel structure CH (e.g., the ferroelectric layer 150). For example, in a plan view, the gate electrode 130 may entirely surround the channel structure CH (e.g., the ferroelectric layer 150). For example, the semiconductor device 10 that includes the ferroelectric layer 150 may have a gate all around (GAA) structure. In this instance, the inner surface 1501 may be an inner side surface of the ferroelectric layer 150, and the outer surface 1502 may be an outer side surface of the ferroelectric layer 150.

In an embodiment, the conductive pattern 160 may be disposed on the inner surface 1501 of the ferroelectric layer 150 that is opposite to the gate electrodes 130. The conductive pattern 160 may have a separated structure (an isolation structure or a cut structure) that is separated to correspond to each gate electrode 130. Here, the phrase that the conductive pattern 160 is separated to correspond to each gate electrode 130 may refer that the conductive pattern 160 is disposed in a region between a first surface 1301 (an upper surface in FIG. 3) of one gate electrode 130 and a second surface 1302 (a lower surface in FIG. 3) of one gate electrode 130 in the extension direction of the channel structure CH (the Z-axis in the drawings).

For example, a first conductive pattern 160a that corresponds to a first gate electrode 130a may be spaced apart from a second conductive pattern 160b that corresponds to a second gate electrode 130b adjacent to the first gate electrode 130a. The first conductive pattern 160a that corresponds to the first gate electrode 130a might not be disposed at a portion where the second gate electrode 130b is disposed in the extension direction of the channel structure CH (the Z-axis direction in the drawings). The second conductive pattern 160b that corresponds to the second gate electrode 130b might not be disposed at a portion where the first gate electrode 130a in the extension direction of the channel structure CH.

In an embodiment, the conductive pattern 160 may correspond to a partial portion of a region (e.g., a unit region UA) where one gate electrode 130 is disposed in the extension direction of the channel structure CH (the Z-axis direction in the drawings). The conductive pattern 160 may partially overlap one of the plurality of gate electrodes 130 in a direction perpendicular to the extension direction. In this instance, the unit region UA may refer to a region that is disposed from the first surface 1301 of one gate electrode 130 and the second surface 1302 of one gate electrode in the extension direction of the channel structure CH (the Z-axis in the drawings).

According, in the unit region UA, the inner surface 1501 of the ferroelectric layer 150 may include a first portion 1501a where the conductive pattern 160 is disposed and a second portion 1501b where the conductive pattern 160 is not disposed.

The conductive pattern 160 may be a floating electrode or a floating gate layer. Here, the floating electrode may refer to an electrode to which a voltage is not applied in a program operation, a read operation, an erase operation, or so on. Accordingly, the semiconductor device 10 may have a structure in which the floating electrode or the floating gate layer having the separated structure is inserted.

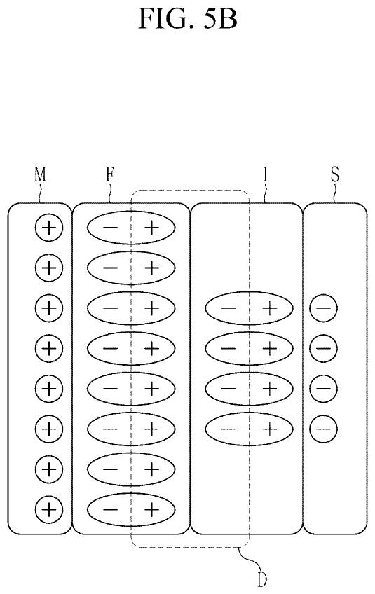

The conductive pattern 160 may compensate polarization charges of the ferroelectric layer 150 so that portions of the ferroelectric layer 150, respectively correspond to the gate electrodes 130, maintain desirable polarization states in an operation of a memory device. The compensation of the polarization charges of the ferroelectric layer 150 will be described later in more detail with reference to FIGS. 5A and 5B.

In an embodiment, the conductive pattern 160 may have the separated structure that is separated to correspond to each gate electrode 130, and thus, unwanted effects on adjacent memory cells may be minimized. For example, the first conductive pattern 160a that corresponds to the first gate electrode 130a may have the separated structure, and thus, unwanted effects of the first conductive pattern 160a on a memory cell that corresponds to the second electrode 130b may be minimized. The second conductive pattern 160b that corresponds to the second gate electrode 130b may have the separated structure, and thus, unwanted effects of the second conductive pattern 160b on a memory cell that corresponds to the first electrode 130a may be minimized.

In an embodiment, the conductive pattern 160 may include a plurality of nanocrystals 162 (e.g., a plurality of first nanocrystals) that are spaced apart from each other in a portion that corresponds to one gate electrode 130. Here, the nanocrystal 162 may refer a crystal that has a nanometer-level width or diameter. A width or a diameter of the nanocrystal 162 may refer to an average width or an average diameter of the nanocrystals 162. For example, the width or the diameter of the nanocrystal 162 may be less than 1 um (e.g., 10 nm or less, as an example, 0.1 nm to 2 nm).

For example, the plurality of nanocrystals 162 may be dispersed to be spaced apart from each other on the inner surface 1501 in a portion that corresponds to one gate electrode 130. In this instance, as illustrated in FIG. 3, in the portion that corresponds to one gate electrode 130, the plurality of nanocrystals 162 may be spaced apart from each other in the extension direction of the channel structure CH (the Z-axis direction in the drawings). As illustrated in FIG. 4, in a plan view, the plurality of nanocrystals 162 may be spaced apart from each other. For example, the plurality of nanocrystals 162 may be spaced apart from each other on a plane (an XY plane in the drawings) that crosses the extension direction of the channel structure CH. In the portion of the inner surface 1501 that corresponds to one gate electrode 130, a portion on which the nanocrystal 162 is disposed may correspond to the first portion 1501a, and a portion between the plurality of nanocrystals 162 may correspond to the second portion 1501b.

In an embodiment, the conductive pattern 160 that is disposed between the ferroelectric layer 150 and the first interfacial insulation layer 152a may be partially disposed in the unit region UA. For example, the conductive pattern 160 (e.g., one or more of the plurality of nanocrystals 162) may be embedded in the first interfacial insulation layer 152a, and/or may be in contact with the ferroelectric layer 150. Accordingly, when the conductive pattern 160 is provided, a portion where the ferroelectric layer 150 and the first interfacial insulation layer 152a are adjacent to (e.g. in contact with) each other may be included. For example, the ferroelectric layer 150 and the first interfacial insulation layer 152a may be adjacent to (e.g. in contact with) each other in the second portion 1501b. In an embodiment, the first interfacial insulation layer 152a may be disposed on the conductive pattern 160 that is disposed on the ferroelectric layer 150. In some embodiments, a layer that is different from the first interfacial insulation layer 152a may be disposed on the conductive pattern 160 that is disposed on the ferroelectric layer 150. Even in this case, when the conductive pattern 160 is provided, a partial portion (e.g., the second portion 1501b) of the ferroelectric layer 150 may be adjacent to (e.g. in contact with) to the layer that is disposed on the conductive pattern 160.

In an embodiment, the conductive pattern 160 may include an interlayer conductive pattern 162i (e.g. a second nanocrystal) in a portion that corresponds to the cell insulation layer 132 (e.g., the interlayer insulation layer 132m) disposed between the plurality of gate electrodes 130. The interlayer conductive pattern 162i (e.g. the second nanocrystal) may be provided in plural. The interlayer conductive pattern 162i that includes nanocrystal 162 has a separated structure, and is spaced apart from portions of the ferroelectric layer 150 that correspond to the gate electrodes 130 and/or the first or second conductive pattern 160a or 160b. Thus, the interlayer conductive pattern 162i might not adversely affect the portions of the ferroelectric layer 150 that correspond to the gate electrodes 130. Accordingly, even when the conductive pattern 160 is provided, there is no need to increase a thickness of the gate electrode 130 and/or an interval between the plurality of gate electrodes 130 in order to prevent disturbance in the extension direction of channel structure CH.

In an embodiment, the channel layer 140 may have an extended structure (an unseparated structure or a continuous structure) in which the channel layer 140 extends in the extension direction of the channel structure CH (the Z-axis direction in the drawings) (e.g., the vertical direction) to correspond to the plurality of gate electrodes 130. At least one of the ferroelectric layer 150 or the first interfacial insulation layer 152a may have an extended structure (an unseparated structure or a continuous structure) that extends in the extension direction of the channel structure CH (the Z-axis direction in the drawings) (e.g., the vertical direction) to correspond to the plurality of gate electrodes 130. For example, each of the ferroelectric layer 150 and the first interfacial insulation layer 152a may have an extended structure that extends in the extension direction of the channel structure CH (the Z-axis direction in the drawings) (e.g., the vertical direction) to correspond to an entire portion where the plurality of gate electrodes 130 are disposed. A side surface of the channel structure CH that corresponds to the gate electrode 130 and a side surface of the channel structure CH that corresponds to the interlayer insulation layer 132m may be disposed on the same plane. The side surface of channel structure CH might not have a recess portion, a depressed portion, a protruding portion, a step, or so on.

In an embodiment, the conductive pattern 160 may include the nanocrystals 162. Even when a process of forming the nanocrystal 162 is entirely performed on the inner surface 1501 of the ferroelectric layer 150, the conductive pattern 160 or the nanocrystal 162 that corresponds to each gate electrode 130 may have the separated structure. Thereby, the conductive pattern 160 that has the separated structure may be formed by an easy process without a patterning process or so on for patterning the conductive pattern 160 to correspond to each gate electrode 130. The ferroelectric layer 150 and/or the first interfacial insulation layer 152a may have the extended structure, and thus, the ferroelectric layer 150 and/or the first interfacial insulation layer 152a may be formed by an easy manufacturing process.

The conductive pattern 160 or the nanocrystal 162 may include or be formed of a material that is capable of sufficiently compensating for polarization charges by including more charges than the first interfacial insulation layer 152a when an electric field is applied. The conductive pattern 160 or the nanocrystal 162 may include a material (e.g., conductive material as a conductive structure) that is different from the first interfacial insulation layer 152a or an insulating material. The conductive pattern 160 or the nanocrystal 162 may include or be formed of a material that is the same as or different from a conductive material that is included in the gate electrode 130.

The conductive pattern 160 or the nanocrystal 162 may include or be formed of a semiconductor material or a metal. More particularly, the nanocrystal 162 may include a semiconductor nanocrystal that includes a semiconductor material or a metal nanocrystal that includes a metal. The nanocrystal 162 that includes the semiconductor material may have a polycrystalline structure, and may include a dopant or might not include a dopant. The nanocrystal 162 that includes the metal may include a single metal material or an alloy. For example, the nanocrystal 162 may include or be formed of silicon, silicon-germanium, tungsten, molybdenum, copper, aluminum, niobium, or combination thereof. However, the embodiments are not limited thereto, and the nanocrystal 162 may include or be formed of any of various materials.

In an embodiment, a thickness T of the conductive pattern 160 or a size of the nanocrystal 162 (e.g., a width or a diameter of the nanocrystal 162) may be less than a thickness T1 of the channel layer 140 or a thickness T2 of the ferroelectric layer 150. Here, the thickness T of the conductive pattern 160, the thickness T1 of the channel layer 140, or the thickness T2 of the ferroelectric layer 150 may refer to a thickness that is measured in a horizontal direction (e.g., an X-axis direction or a Y-axis direction in the drawings) or a direction that is perpendicular to a side surface of the channel structure CH, and for example, a maximum thickness or an average thickness. The size of the nanocrystal 162 (e.g., the width or the diameter of the nanocrystal 162) may refer to an average size (e.g., an average width or an average diameter). Thereby, process time of forming the conductive pattern 160 or the nanocrystal 162 may be reduced and structural stability may be maintained. However, the embodiments are not limited thereto. The thickness T of the conductive pattern 160 or the size of the nanocrystal 162 (e.g., the width or the diameter of the nanocrystal 162) may be the same as or greater than the thickness T1 of the channel layer 140 or the thickness T2 of the ferroelectric layer 150.

In an embodiment, the thickness T of the conductive pattern 160 or the size of the nanocrystal 162 (e.g., the width or the diameter of the nanocrystal 162) may be less than, be the same as, or be greater than a thickness of the first interfacial insulation layer 152a. Here, the thickness of the first interfacial insulation layer 152a may refer to a thickness that is measured in the horizontal direction (e.g., the X-axis direction or the Y-axis direction in the drawings) or the direction that is perpendicular to the side surface of the channel structure CH, and for example, a maximum thickness or an average thickness.

An operation method of a semiconductor device 10 (e.g., a ferroelectric memory device) will be described in more detail with reference to FIG. 3, FIG. 5A, and FIG. 5B. The semiconductor device 10 (e.g., the ferroelectric memory device) may include a gate stacking structure 120 that includes a gate electrode 130 and a channel structure CH that includes a ferroelectric layer 150. In a right enlarged portion of FIG. 3, a polarization direction of the ferroelectric layer 150 in a program operation is illustrated. FIG. 5A conceptually illustrates a charge distribution in the gate electrode 130 and the channel structure CH that are included in the semiconductor device 10 illustrated in FIG. 1 when the ferroelectric layer 150 is in a first polarization state. FIG. 5B conceptually illustrates a charge distribution in a comparative example in which a conductive pattern is not included. In FIG. 5A, a charge distribution in the gate electrode 130, the ferroelectric layer 150, the conductive pattern 160, the first interfacial insulation layer 152a, and the channel layer 140 in the embodiment is illustrated. In FIG. 5B, a charge distribution in a gate electrode M, a ferroelectric layer F, an interfacial insulation layer I, and a channel layer S in the comparative example is illustrated.

Referring to FIG. 3, in a program operation, voltages may be applied to the gate electrode 130, the channel layer 140, or so on so that a first region P1 of the ferroelectric layer 150 that corresponds to a first gate electrode 130a, which is a selected gate electrode, has a first polarization state and a second region P2 of the ferroelectric layer 150 that corresponds to a second gate electrode 130b, which is an unselected gate electrode, has a second polarization state.

In an embodiment, in the first polarization state, positive charges may be accumulated to a side of an inner surface 1501 of the ferroelectric layer 150 that is close to the channel layer 140, and negative charges may be disposed at a side of an outer surface 1502 of the ferroelectric layer 150 that is close to the gate electrode 130. Accordingly, a selected transistor that includes the first gate electrode 130a, which is the selected gate electrode, may have a relatively low threshold voltage.

In this instance, as illustrated in FIG. 5A, the gate electrode 130 may compensate the polarization charges at the side of the outer surface 1502 of the ferroelectric layer 150. The conductive pattern 160 may compensate the polarization charges at the side of the inner surface 1501 of the ferroelectric layer 150. The conductive pattern 160 may include the semiconductor material or the metal, and thus, may have sufficient charges when an electric field is applied. As illustrated in a portion C in FIG. 5A, the conductive pattern 160 may sufficiently compensate the polarization charges at the side of the inner surface 1501 of the ferroelectric layer 150. As such, by negative charges of the conductive pattern 160, a state in which positive charges are accumulated at the side of the inner surface 1501 of the ferroelectric layer 150 may be stably maintained. As a result, the first polarization state may be stably maintained. That is, in an embodiment, a lack of compensation for polarization charges that may occur at the side of the inner surface 1501 of the ferroelectric layer 150 opposite to the gate electrode 130 may be prevented or minimized by the conductive pattern 160 that is adjacent to the inner surface 1501 of the ferroelectric layer 150. By the compensation of the polarization charges, unwanted depolarization may be suppressed.

On the other hand, in a comparative example in which a conductive pattern is not included, a gate electrode M may compensate polarization charges at a side of an outer surface of a ferroelectric layer F that is close to a gate electrode M, but compensation of polarization charges at a side of an inner surface of the ferroelectric layer F that opposite to the gate electrode M might not be sufficient. That is, as illustrate in a D portion in FIG. 5B, an interfacial insulation layer I that includes an insulating material does not have sufficient charges even when an electric field is applied, and thus, the interfacial insulation layer I might not sufficiently compensate the polarization charges at the side of the inner surface of the ferroelectric layer F. As a result, it is difficult to stably maintain a first polarization state in the ferroelectric layer F, and thus, depolarization may occur.

In the second region P2 that has the second polarization state, negative charges may be accumulated to be close to the channel layer 140, and positive charges may be far away from the channel layer 140. Accordingly, an unselected transistor that includes the second gate electrode 130b, which is the unselected gate electrode, may have a relatively high threshold voltage.

In a read operation, the current that flows through the channel layer 140 in the selected transistor and the current that flows through the channel layer 140 in the unselected transistor may be different from each other by a difference between the threshold voltage of the first polarization state and the threshold voltage of the second polarization state. Accordingly, the selected transistor and the unselected transistor may be determined or distinguished by using the difference in current that flows through the channel layer 140. In this instance, the selected transistor that has the first polarization state may have the relatively low threshold voltage and thus a relatively large amount of a current may flow through the selected transistor, while the unselected transistor that has the second polarization state may have the relatively high threshold voltage and thus a relatively low amount of a current may flow through the selected transistor.

In an erase operation, voltages may be applied to the gate electrode 130, the channel layer 140, or so on so that portions of the ferroelectric layer 150 that correspond to the gate electrodes 130, respectively, have the second polarization state.

The semiconductor device 10 that includes the channel structure CH including the ferroelectric layer 150 may maintain data without an externally applied electric field, have a relatively low operating voltage, and have a fast operating speed.

In an embodiment, in the semiconductor device 10 (e.g., the ferroelectric memory device) that includes the ferroelectric layer 150, polarization charges may be sufficiently compensated by the conductive pattern 160 that is disposed on the inner surface 1501 of the ferroelectric layer 150, and thus, depolarization may be suppressed. Accordingly, disturbance that may occur due to the depolarization may be prevented and retention may be enhanced. Accordingly, performance and reliability of the semiconductor device 10 may be enhanced.

A manufacturing method of a semiconductor device 10 according to an embodiment will be briefly described.

A plurality of sacrificial insulation layers and a plurality of cell insulation layers 132 may be alternately formed on a second substrate 110 to form a stacking structure. The sacrificial insulation layer may include or be formed of a material that is different from a material of the cell insulation layer 132 (e.g., an interlayer insulation layer 132m). For example, the sacrificial insulation layer may include or be formed of silicon, silicon oxide, silicon carbide, silicon nitride, or so on, which is different from the material of the cell insulation layer 132 (e.g., the interlayer insulation layer 132m).

A penetrating portion may be formed at least at a partial portion of a cell array region 102 to correspond to a channel structure CH. A ferroelectric layer 150, a conductive pattern 160, a first interfacial insulation layer 152a, a channel layer 140, a core insulation layer 142, a channel pad 144, or so on may be formed in the penetrating portion to form the channel structure CH. In this instance, the conductive pattern 160 that includes the nanocrystals 162 may be formed on the inner surface 1501 of the ferroelectric layer 150 by using any of various methods. For example, the conductive pattern 160 that includes the nanocrystals 162 may be formed by a deposition (e.g., chemical vapor deposition or so on) under a process condition that is capable of forming the nanocrystals 162.

An opening for a separation structure that corresponds to a separation structure 146 may be formed in the stacking structure and the sacrificial insulation layers may be removed through the opening for the separation structure. Gate electrodes 130 may be formed in portions where the sacrificial insulation layers are removed to form a gate stacking structure 120. The separation structure 146 may be formed by filling an insulating material or so on in the opening for the separation structure. Thereby, a cell region 100 may be formed.

Hereinafter, referring to FIG. 6 to FIG. 18, semiconductor devices and manufacturing methods of the semiconductor devices according to embodiments will be described in detail. To the extent that an element is not described in detail below, it may be understood that the element is at least substantially similar (and/or the same as) to a corresponding element that has been described elsewhere within the present disclosure. A portion which is not described in the above will be described in detail.

FIG. 6 is a partial cross-sectional view that illustrates a partial portion of a memory cell structure included in a semiconductor device according to an embodiment. FIG. 6 illustrates a portion that corresponds to FIG. 3.

Referring to FIG. 6, in an embodiment, an interfacial insulation layer 152 may include a first interfacial insulation layer 152a and a second interfacial insulation layer 152b.

The first interfacial insulation layer 152a may extend in an extension direction of a channel structure CH or a vertical direction (a z-axis direction in the drawings) between a portion, which includes a ferroelectric layer 150 and a conductive pattern 160, and a channel layer 140. The second interfacial insulation layer 152b may extend in the extension direction of the channel structure CH or the vertical direction (the z-axis direction in the drawings) between gate electrodes 130 and the ferroelectric layer 150.

The first interfacial insulation layer 152a or the second interfacial insulation layer 152b may include or be formed of silicon oxide (SiOₓ), silicon nitride (SiNₓ), silicon oxynitride (SiONₓ), aluminum oxide (AIO), aluminum oxynitride (AlONₓ), hafnium oxide (HfO), a high dielectric constant material that has a higher dielectric constant than silicon oxide, or a combination thereof. The first interfacial insulation layer 152a may include or be formed of a material that is the same as or is different from a material of the second interfacial insulation layer 152b.

In FIG. 6, it is illustrated as an example that the interfacial insulation layer 152 includes the first interfacial insulation layer 152a and the second interfacial insulation layer 152b, but the embodiments are not limited thereto. For example, the interfacial insulation layer 152 may include the second interfacial insulation layer 152b and might not include the first interfacial insulation layer 152a.

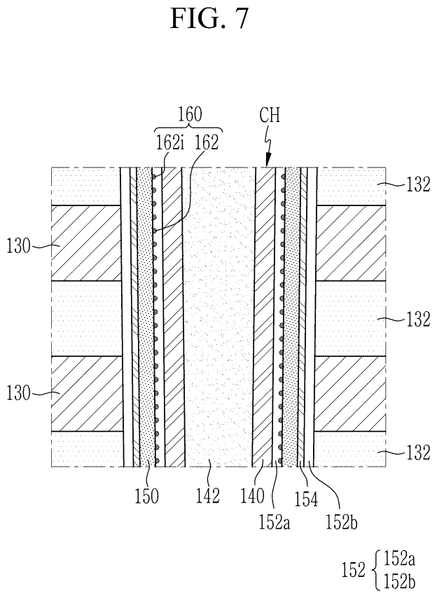

FIG. 7 is a partial cross-sectional view that illustrates a partial portion of a memory cell structure included in a semiconductor device according to an embodiment. FIG. 7 illustrates a portion that corresponds to FIG. 3.

Referring to FIG. 7, in an embodiment, an interfacial insulation layer 152 may include a first interfacial insulation layer 152a and a second interfacial insulation layer 152b, and a channel structure CH may further include a charge trap layer 154 that is disposed between gate electrodes 130 and a ferroelectric layer 150 (more particularly, between the second interfacial insulation layer 152b and the ferroelectric layer 150).

The charge trap layer 154 may extend in an extension direction of the channel structure CH (a z-axis direction in the drawings), for example, a vertical direction, between the second interfacial insulation layer 152b and the ferroelectric layer 150. The description with reference to FIG. 1 to FIG. 6 may be applied to the first interfacial insulation layer 152a and the second interfacial insulation layer 152b as is.

The charge trap layer 154 may include or be formed of at least one of silicon oxide (SiOₓ), silicon nitride (SiNₓ), silicon oxynitride (SiONₓ), aluminum oxide (AlOₓ), hafnium oxide (HfOₓ), or a nanocrystal, or a combination thereof. For example, the charge trap layer 154 may include or be formed of at least one of SiOₓ, SiNₓ, SiONₓ, a stacked structure of SiOₓ/SiNₓ, a stacked structure of SiOₓ/SiONₓ, a stacked structure of SiOₓ/AlOₓ, a stacked structure of SiOₓ/HfOₓ, a stacked structure of SiOₓ/SiNₓ/SiOₓ, or a stacked structure of SiOₓ/a nanocrystal. However, the embodiments are not limited thereto, and the charge trap layer 154 may include any of various materials.

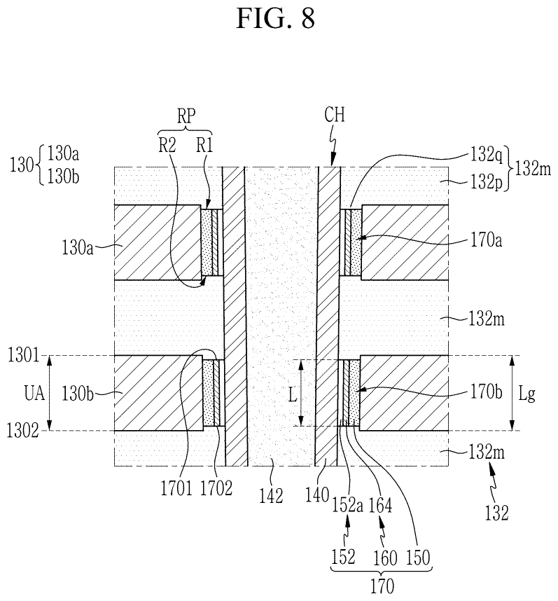

FIG. 8 is a partial cross-sectional view that illustrates a partial portion of a memory cell structure included in a semiconductor device according to an embodiment. FIG. 8 illustrates a portion that corresponds to FIG. 3.

Referring to FIG. 8, in an embodiment, a channel structure CH may include a channel layer 140, and a separated stacking portion 170. The separated stacking portion 170 may be disposed between the channel layer 140 and gate electrodes 130 and have a separated structure that is separated to correspond to each gate electrode 130. The channel structure CH may further include a core insulation layer 142 and a channel pad 144 (refer to FIG. 2). In some embodiments, the core insulation layer 142 may be omitted.

In an embodiment, a stacking portion or the separated stacking portion 170 that is disposed between the channel layer 140 and the gate electrode 130 may include at least a ferroelectric layer 150 and a conductive pattern 160, and further include an interfacial insulation layer 152 that includes a first interfacial insulation layer 152a. The conductive pattern 160 may be referred to as a conductive structure. The conductive pattern 160 may have a separated structure (an isolation structure or a cut structure) that is separated to correspond to each gate electrode 130. The ferroelectric layer 150 and/or the first interfacial insulation layer 152a may have a separated structure that is separated to correspond to each gate electrode 130. In this instance, the conductive pattern 160 may include a conductive layer 164 of a layer shape that corresponds to each gate electrode 130. However, the embodiments are not limited thereto. The plurality of layers that are included in the stacking portion or the separated stacking portion 170 may be variously modified.

For example, a first separated stacking portion 170a that corresponds to a first gate electrode 130a may be spaced apart from a second separated stacking portion 170b that corresponds to a second gate electrode 130b adjacent to the first gate electrode 130a. The first separated stacking portion 170a that corresponds to the first gate electrode 130a might not be disposed at a portion where the second gate electrode 130b is disposed in the extension direction of the channel structure CH (the Z-axis direction in the drawings). The second separated stacking portion 170b that corresponds to the second gate electrode 130b might not be disposed at a portion where the first gate electrode 130a is disposed in the extension direction of the channel structure CH.

For example, a conductive pattern 160 (e.g., a first conductive pattern 160a) that corresponds to the first gate electrode 130a may be spaced apart from a conductive pattern 160 (e.g., a second conductive pattern 160b) that corresponds to the second gate electrode 130b. The conductive pattern 160 or the conductive layer 164 might not be disposed at a portion that corresponds to a cell insulation layer 132 (e.g., an interlayer insulation layer 132m) between the plurality of gate electrodes 130. Thereby, unwanted effects of the conductive pattern 160 or the conductive layer 164 on another portion of the ferroelectric layer 150 that corresponds to an adjacent gate electrode 130 may be prevented or minimized.

In an embodiment, the separated stacking portion 170 may correspond to a partial portion of a region (e.g., a unit region UA) that corresponds to each gate electrode 130. For example, at least one of the ferroelectric layer 150, the conductive layer 164, or the first interfacial insulation layer 152a may correspond to a partial portion of the unit region UA.

Accordingly, in the extension direction of the channel structure CH, the unit region UA may include a portion in which at least a partial portion of the separated stacking portion 170 is disposed and another portion in which the separated stacking portion 170 is not disposed. For example, in the extension direction of the channel structure CH, the unit region UA may include a portion in which the ferroelectric layer 150, the conductive pattern 160, or the first interfacial insulation layer 152a is disposed and another portion in which the ferroelectric layer 150, the conductive pattern 160, or the first interfacial insulation layer 152a is not disposed.

In an embodiment, at least one of the plurality of separated stacking portions 170 may include a recess portion RP to be disposed inside the gate electrode 130 in the extension direction of the channel structure CH (the Z-axis direction in the drawings). The phrase that the separated stacking portion 170 is disposed inside the gate electrode 130 in the extension direction of the channel structure CH may refer to a case that a distance between a surface of the separated stacking portion 170 that crosses the extension direction of the channel structure CH and a central portion of the gate electrode 130 in the extension direction of the channel structure CH is less than a distance between a first surface 1301 or a second surface 1302 of the gate electrode 130 and the central portion of the gate electrode 130 in the extension direction of the channel structure CH. The surface of the separated stacking portion 170 that crosses the extension direction of the channel structure CH may refer to a first surface 1701 of the separated stacking portion 170 (e.g., a first side surface or an upper surface in FIG. 8) or a second surface 1702 of the separated stacking portion 170 (e.g., a second side surface or a lower surface in FIG. 8).

For example, recess portions RP may be respectively provided on the first surface 1701 of the separated stacking portion 170 and the second surface 1702 of the separated stacking portion 170 that are opposite to each other in the extension direction of the channel structure CH (the Z-axis direction in the drawings). That is, the recess portion RP may include a first recess portion R1 that is disposed at a side of the first surface 1701 of the separated stacking portion 170 and a second recess portion R2 that is disposed at a side of the second surface 1702 of the separated stacking portion 170. For example, at least one of the ferroelectric layer 150, the conductive pattern 160, or the first interfacial insulation layer 152a may include the recess portion RP, for example, the first recess portion R1 and/or the second recess portion R2.

By the first recess portion R1, the first surface 1301 of the gate electrode 130 and the first surface 1701 of the separated stacking portion 170 that are far away from the second substrate 110 may include portions at different positions in the extension direction of the channel structure CH (the Z-axis direction in the drawings). More particularly, by the first recess portion R1, at least a partial portion of the first surface 1701 of the separated stacking portion 170 may be disposed below the first surface 1301 of the gate electrode 130 in the extension direction of the channel structure CH. For example, by the first recess portion R1, at least a partial portion of a first surface of the ferroelectric layer 150, a first surface of the conductive pattern 160, a first surface of the conductive layer 164, and/or a first surface of the first interfacial insulation layer 152a may be disposed below the first surface 1301 of the gate electrode 130 in the extension direction of the channel structure CH.

By the second recess portion R2, the second surface 1302 of the gate electrode 130 and the second surface 1702 of the separated stacking portion 170 that are close to the second substrate 110 may include portions at different positions in the extension direction of the channel structure CH (the Z-axis direction in the drawings). More particularly, by the second recess portion R2, at least a partial portion of the second surface 1702 of the separated stacking portion 170 may be disposed above the second surface 1302 of the gate electrode 130 in the extension direction of the channel structure CH. For example, by the second recess portion R2, at least a partial portion of a second surface of the ferroelectric layer 150, a second surface of the conductive pattern 160, a second surface of the conductive layer 164, and/or a second surface of the first interfacial insulation layer 152a may be disposed above the second surface 1302 of the gate electrode 130 in the extension direction of the channel structure CH.

Accordingly, in the extension direction of the channel structure CH (the Z-axis direction in the drawings), a length L of the separated stacking portion 170 that corresponds to one gate electrode 130 may be less than a thickness Lg of one gate electrode 130. For example, the thickness Lg of one gate electrode 130 may refer to a maximum thickness or an average thickness, and the length L of the separated stacking portion 170 may refer to a minimum length or an average length.

For example, in the extension direction of the channel structure CH (the Z-axis direction in the drawings), a length of the ferroelectric layer 150 that corresponds to one gate electrode 130 may be less than the thickness Lg of one gate electrode 130. For example, in the extension direction of the channel structure CH (the Z-axis direction in the drawings), a length of the conductive pattern 160 or the conductive layer 164 that corresponds to one gate electrode 130 may be less than the thickness Lg of one gate electrode 130. For example, in the extension direction of the channel structure CH (the Z-axis direction in the drawings), a length of the first interfacial insulation layer 152a that corresponds to one gate electrode 130 may be less than the thickness Lg of one gate electrode 130. Here, a phrase that the length is less than the thickness may include a case where the length in an entire portion is less than the thickness and a case where the length in at least a partial portion is less than the thickness.

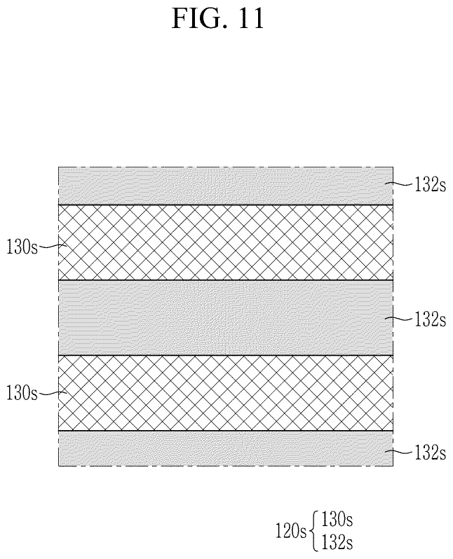

In a comparative example, a penetrating portion for a channel structure is formed, a partial portion of a sacrificial insulation layer 130s (refer to FIG. 11) is removed to form an expanded portion, and a stacking portion is formed in the expanded portion. Accordingly, unlike the embodiment, a length of a ferroelectric layer is the same as or greater than a thickness of a gate electrode in an extension direction of the channel structure.

The conductive pattern 160 or the conductive layer 164 may include or be formed of a material that is capable of sufficiently compensating for polarization charges by including more charges than the first interfacial insulation layer 152a when an electric field is applied. The conductive pattern 160 or the conductive layer 164 may include or be formed of a material (e.g., a conductive material) that is different from a material of the first interfacial insulation layer 152a or an insulating material. The conductive pattern 160 or the conductive layer 164 may include or be formed of a conductive material that is the same as or different from a conductive material of the gate electrode 130.

The conductive pattern 160 or the conductive layer 164 may include or be formed of a semiconductor material or a metal. More particularly, the conductive layer 164 may include a semiconductor material, a single metal material, an alloy, or metal nitride. The conductive layer 164 that includes the semiconductor material may have a polycrystalline structure, and may include a dopant or might not include a dopant. For example, conductive layer 164 may include silicon, silicon-germanium, tungsten, molybdenum, copper, aluminum, niobium, titanium nitride (TIN), tantalum nitride (TaN), tungsten nitride (WN), or combination thereof. However, the embodiments are not limited thereto. The conductive layer 164 may include or be formed of any of various materials.

In an embodiment, a thickness of the conductive pattern 160 or a thickness of the conductive layer 164 may be less than a thickness of the channel layer 140 or a thickness of the ferroelectric layer 150. Accordingly, process time of forming the conductive pattern 160 or the conductive layer 164 may be reduced and structural stability may be maintained. However, the embodiments are not limited thereto. The thickness of the conductive pattern 160 may be the same as or greater than the thickness of the channel layer 140 or the thickness of the ferroelectric layer 150.

In an embodiment, the thickness of the conductive pattern 160 may be less than, be the same as, or be greater than the thickness of the first interfacial insulation layer 152a.

In an embodiment, the cell insulation layer 132 (e.g., the interlayer insulation layer 132m) may include a first insulation portion 132p and a second insulation portion 132q. The first insulation portion 132p may be disposed between the plurality of gate electrodes 130 in the extension direction of the channel structure CH. The second insulation portion 132q may be disposed between the plurality of separated stacking portions 170 in the extension direction of the channel structure CH and protrude than the first insulation portion 132p. More particularly, in the extension direction of the channel structure CH, the second insulation portion 132q may outwardly protrude than the first insulation portion 132p. This may be because the interlayer insulation layer 132m is formed in a portion that is formed by removing a preliminary cell insulation layer 132s and a partial portion of a preliminary stacking portion 170p and includes the recess portion RP.

In FIG. 8, it is illustrated as an example that a surface (i.e., the first surface 1701 or the second surface 1702) of the separated stacking portion 170 that crosses the extension direction of the channel structure CH in the recess portion RP has a flat surface (an XY plane in the drawings) that is perpendicular to the extension direction of the channel structure CH. That is, in the extension direction of the channel structure CH, lengths of the ferroelectric layer 150, and the conductive layer 164 and the interfacial insulation layer 152 included in the separated stacking portion 170 may be substantially the same as each other. However, the embodiments are not limited thereto.

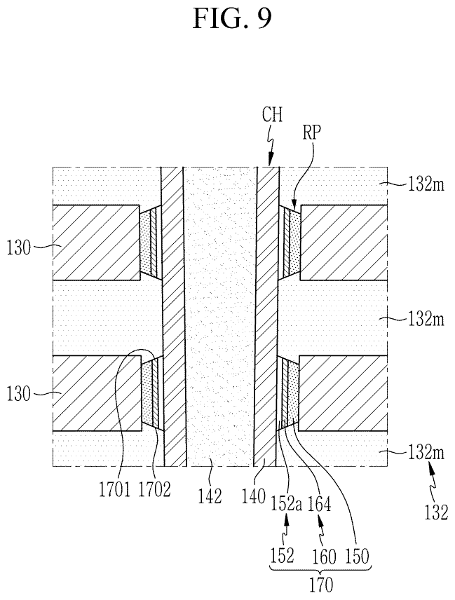

As illustrated in FIG. 9, a portion of a separated stacking portion 170 that is close to the gate electrode 130 and another portion of the separated stacking portion 170 that is close to the channel layer 140 may have different lengths in an extension direction of a channel structure CH. For example, in the extension direction of the channel structure CH, a length of a portion of the separated stacking portion 170 that is close to the gate electrode 130 may be less than a length of another portion of the separated stacking portion 170 that is close to the channel layer 140.

For example, a first surface 1701 or a second surface 1702 of the separated stacking portion 170 may include an inclined surface so that the length of the separated stacking portion 170 increases from a portion of the separated stacking portion 170 that is close to the gate electrode 130 to another portion of the separated stacking portion 170 that is close to the channel layer 140. For example, the length may refer to a minimum length or an average length. That is, a length of each of a ferroelectric layer 150, a conductive layer 164, and a first interfacial insulation layer 152a that are included in the separated stacking portion 170 may gradually increase. The length may be measured in the extension direction of the channel structure CH. This may be because the portion that is close to the gate electrode 130 may be exposed more and be etched more in a process of removing a partial portion of the preliminary stacking portion 170p. Thereby, a recess portion RP (e.g., a first recess portion R1 and/or a second recess portion R2) may have an inclined surface.

In FIG. 9, it is illustrated as an example that the first surface 1701 or the second surface 1702 of the separated stacking portion 170 has the inclined surface, but the embodiments are not limited thereto. The first surface 1701 or the second surface 1702 of the separated stacking portion 170 may have a rounded surface. In some embodiments, a length of a portion of the separated stacking portion 170 that is close to the gate electrode 130 in the extension direction of the channel structure CH may be greater than a length of another portion of the separated stacking portion 170 that is close to the channel layer 140 in the extension direction of the channel structure CH.

In an embodiment, the channel layer 140 may have an extended structure (an unseparated structure or a continuous structure) in which the channel layer 140 extends in the extension direction of the channel structure CH (the Z-axis direction in the drawings) (e.g., a vertical direction) to correspond to the plurality of gate electrodes 130. That is, a plurality of separated stacking portions 170 that have the separated structure to be spaced apart from each other may be disposed on the channel layer 140 that has the extended structure. The plurality of separated stacking portions 170 may a protruding structure that protrudes from the channel layer 140 to an outside (e.g., an outside in a horizontal direction). Thereby, a side surface of the channel structure CH that corresponds to the gate electrode 130 and a side surface of the channel structure CH that corresponds to the interlayer insulation layer 132m may be disposed on different planes. The side surface of channel structure CH may have a recess portion, a depressed portion, a protruding portion, a step, or so on.

In FIG. 8 and FIG. 9, it is illustrated as an example that the conductive pattern 160, which is included in the separated stacking portion 170 that has the separated structure, includes the conductive layer 164. However, the embodiments are not limited thereto. The conductive pattern 160, which is included in the separated stacking portion 170, may include a plurality of nanocrystals 162 described with reference to FIG. 1 to FIG. 7. In this case, the conductive pattern 160 might not include an interlayer conductive pattern 162i (refer to FIG. 3) that is disposed in a portion, which corresponds to a cell insulation layer 132 (e.g., an interlayer insulation layer 132m) between a plurality of gate electrodes 130.

In FIG. 8 and FIG. 9, it is illustrated as an example that each of a plurality of layers (e.g., the ferroelectric layer 150, the conductive layer 164, and the first interfacial insulation layer 152a), which are included in the stacking portion between the gate electrode 130 and the channel layer 140 has the separated structure. However, the embodiments are not limited thereto. At least one layer (e.g., a first interfacial insulation layer 152a) among the plurality of layers included in the stacking portion may have an extended structure (an unseparated structure or a continuous structure), instead of the separated structure.

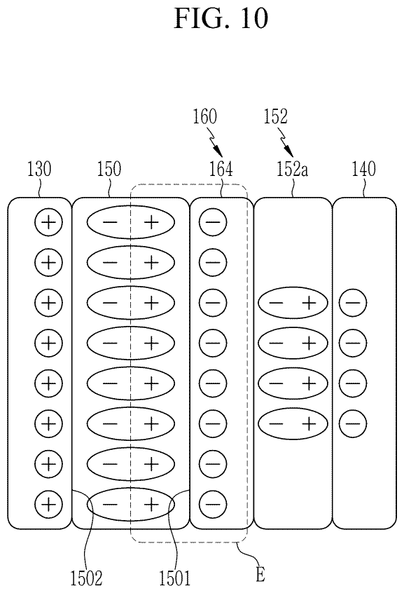

Compensation of polarization charges by a conductive pattern 160 or a conductive layer 164 in a semiconductor device 10 (e.g., a ferroelectric memory device) will be described later in more detail with reference to FIG. 10, together with FIG. 8. The semiconductor device 10 (e.g., the ferroelectric memory device) may include a gate stacking structure 120 that includes a gate electrode 130 and a channel structure CH that includes a ferroelectric layer 150. FIG. 10 conceptually illustrates a charge distribution in the gate electrode 130 and the channel structure CH that are included in the semiconductor device 10 illustrated in FIG. 8 when the ferroelectric layer 150 is in a first polarization state. FIG. 10 illustrates a charge distribution in the gate electrode 130, the ferroelectric layer 150, the conductive pattern 160, a first interfacial insulation layer 152a, and a channel layer 140.

Referring to FIG. 8 and FIG. 10, in an embodiment, in a first polarization state, positive charges may be accumulated to a side of an inner surface 1501 of the ferroelectric layer 150 that is close to the channel layer 140, and negative charges may be disposed at a side of the outer surface 1502 of the ferroelectric layer 150 that is close to the gate electrode 130.

As illustrated in FIG. 10, the gate electrode 130 may compensate polarization charges at the side of the outer surface 1502 of the ferroelectric layer 150. The conductive pattern 160 may compensate the polarization charges at the side of the inner surface 1501 of the ferroelectric layer 150. The conductive pattern 160 may include the semiconductor material or the metal, and thus, may have sufficient charges when an electric field is applied. Accordingly, as illustrated in a portion E of FIG. 10, the conductive pattern 160 may sufficiently compensate the polarization charges at the side of the inner surface 1501 of the ferroelectric layer 150. By the compensation of the polarization charges, unwanted depolarization may be suppressed.

Referring to FIG. 11 to FIG. 15, a manufacturing method of a semiconductor device 10 illustrated in FIG. 8 will be described in detail. To the extent that an element is not described in detail below, it may be understood that the element is at least substantially similar (and/or the same as) to a corresponding element that has been described elsewhere within the present disclosure. A portion which is not described in the above will be described in detail.

FIG. 11 to FIG. 15 are cross-sectional views that illustrate a manufacturing method of a semiconductor device according to an embodiment. FIG. 11 to FIG. 15 illustrates a portion that corresponds to FIG. 8. Regarding the manufacturing method of the semiconductor device, a manufacturing method of a gate stacking structure 120 and a channel structure CH will be mainly described.

As illustrated in FIG. 11, a stacking structure 120s may be formed by alternately stacking sacrificial insulation layers 130s and preliminary cell insulation layer 132s on a second substrate 110 (refer to FIG. 1). For example, a horizontal insulation layer 116 (refer to FIG. 1) and a second horizontal conductive layer 114 (refer to FIG. 1) may be formed on the second substrate 110, and then, the stacking structure 120s may be formed thereon.

The sacrificial insulation layer 130s may be a layer that will be replaced with a gate electrode 130 (refer to FIG. 1) through a subsequent process. At least a partial portion of the horizontal insulation layer 116 may be a layer that will be replaced with a first horizontal conductive layer 112 (refer to FIG. 1) through a subsequent process. That is, the sacrificial insulation layer 130s may be formed to correspond to a portion where the gate electrode 130 will be formed, and the horizontal insulation layer 116 may be formed to include a portion where the first horizontal conductive layer 112 will be formed.

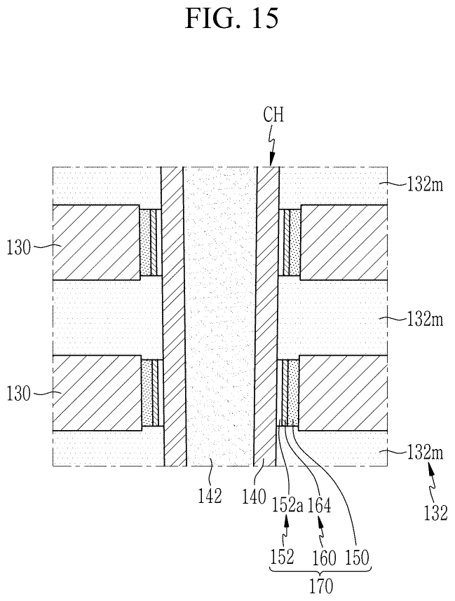

The preliminary cell insulation layer 132s may be a layer that will be replaced with a cell insulation layer 132 (refer to FIG. 15), for example, an interlayer insulation layer 132m (refer to FIG. 15). The preliminary cell insulation layer 132s may be formed to correspond to a partial portion of a region where the cell insulation layer 132 will be formed.

The horizontal insulation layer 116 and/or the sacrificial insulation layer 130s may include or be formed of a material that is different from a material of the cell insulation layer 132 or the preliminary cell insulation layer 132s. For example, the cell insulation layer 132 or the preliminary cell insulation layer 132s may include silicon oxide, silicon nitride, silicon oxynitride, a low dielectric constant material, or so on, and/or the sacrificial insulation layer 130s may include silicon, silicon oxide, silicon carbide, silicon nitride, or so on that is different from the material of the cell insulation layer 132 or the preliminary cell insulation layer 132s.

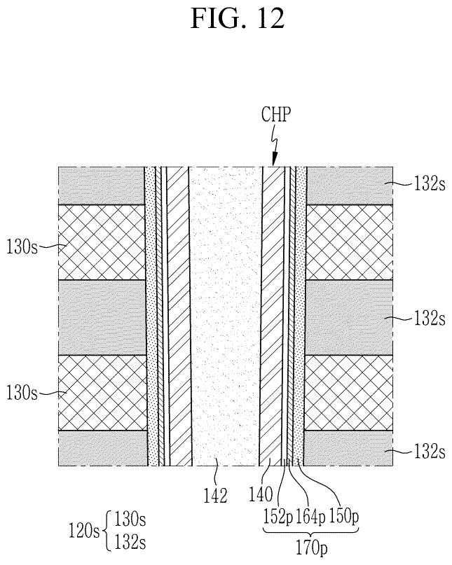

Subsequently, as illustrated in FIG. 12, a penetrating portion that pass through the stacking structure 120s may be formed, and a preliminary stacking portion 170p, a channel layer 140, a core insulation layer 142, a channel pad 144 (refer to FIG. 2), or so on may be formed in the penetrating portion to form a preliminary channel structure CHP. For example, the preliminary stacking portion 170p may include a preliminary ferroelectric layer 150p, a preliminary conductive layer 164p, and a first preliminary interfacial insulation layer 152p that are sequentially formed.

The penetrating portion may pass through the stacking structure 120s to provide a space where a channel structure CH is formed. The penetrating portion may be formed by an etching process. Here, the penetrating portion may have any shape that corresponds to a shape of the preliminary channel structure CHP and entirely pass through the stacking structure 120s, and the embodiments are not limited to a shape of the penetrating portion.

The preliminary ferroelectric layer 150p, the preliminary conductive layer 164p, the first preliminary interfacial insulation layer 152p, the channel layer 140, the core insulation layer 142, or the channel pad 144 may be formed by using an atomic layer deposition process or a chemical vapor deposition process. However, the embodiments are not limited thereto. Other various processes may be applied.

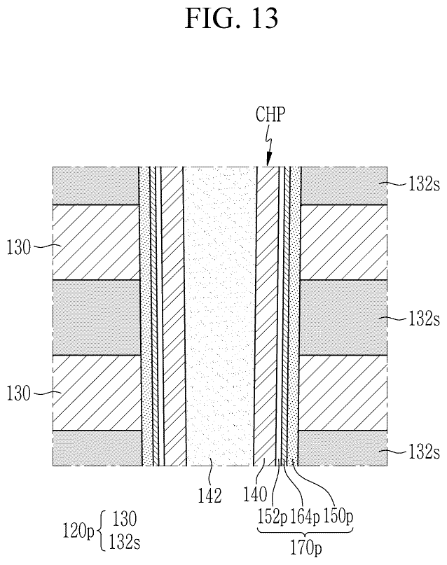

Subsequently, as illustrated in FIG. 13, the sacrificial insulation layers 130s (refer to FIG. 12) may be removed and gate electrodes 130 may be formed in regions where the sacrificial insulation layers 130s were disposed to form a preliminary gate stacking structure 120p.

For example, an opening for a separation structure may be formed to pass through the stacking structure 120s (refer to FIG. 12). The opening for the separation structure may be formed in a portion where a separation structure 146 (refer to FIG. 1) will be formed. The sacrificial insulation layers 130s may be selectively removed by an etching process through the opening for the separation structure. The gate electrodes 130 may be formed by filling portions from which the sacrificial insulation layers 130s were removed with a conductive material. The opening for the separation structure may be formed to expose the horizontal insulation layer 116. At least a partial portion of the horizontal insulation layer 116 may be removed in an etching process through the opening for the separation structure, and a first horizontal conductive layer 112 may be formed by filling a material of the first horizontal conductive layer 112.

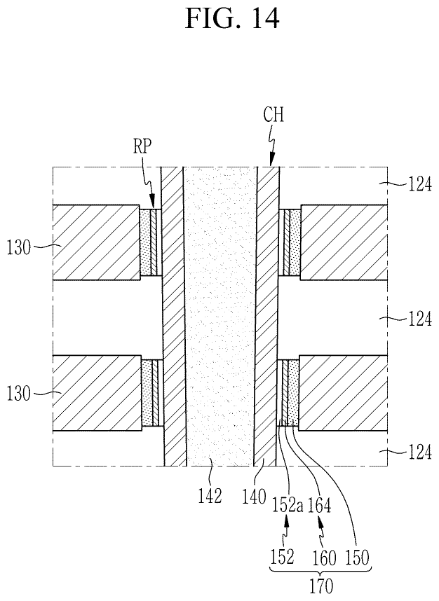

Subsequently, as illustrated in FIG. 14, the preliminary cell insulation layer 132s (refer to FIG. 13) and a partial portion of the preliminary stacking portion 170p (refer to FIG. 13) may be removed. Thereby, a separated stacking portion 170 that has a recess portion RP may be formed.

More particularly, by an etching process through the opening for the separation structure, the preliminary cell insulation layers 132s and a partial portion of the preliminary stacking portion 170p may be selectively removed. The removed partial portion of the preliminary stacking portion 170p may include a portion that corresponds to the preliminary cell insulation layer 132s in an extension direction of the channel structure CH. By removing the partial portion of the preliminary stacking portion 170p that includes the portion corresponding to the preliminary cell insulation layer 132s, the separated stacking portion 170 that has a recess portion RP may be formed. A space portion 124 may be disposed between the preliminary cell insulation layers 132s and between the separated stacking portions 170 in the extension direction of the channel structure CH.

For example, the preliminary cell insulation layers 132s may be removed by an etching process, and the partial portion of the preliminary stacking portion 170p may be removed by an etching process or a dry cleaning process.

However, the embodiments are not limited thereto. The preliminary stacking portion 170p may be removed by any of various processes.

As illustrated in FIG. 15, the space portions 124 (refer to FIG. 14) may be filled to form cell insulation layers 132, for example, interlayer insulation layers 132m. The cell insulation layer 132, for example, the interlayer insulation layer 132m may be formed by any of various processes such as deposition or so on.

In an embodiment, the interlayer insulation layer 132m may include a first insulation portion and a second insulation portion. The first insulation portion may be disposed between the plurality of gate electrodes 130 in the extension direction of the channel structure CH. The second insulation portion may be disposed between the plurality of separated stacking portions 170 in the extension direction of the channel structure CH. The separated stacking portion 170 may have the recess portion RP to be disposed inside the gate electrode 130, and thus, the second insulation portion may outwardly protrude than the first insulation portion.

In an embodiment, a replacement process where the sacrificial insulation layers 130s are removed and replaced with the gate electrodes 130, and a replacement process where the preliminary cell insulation layers 132s and the partial portions of the preliminary stacking portion 170p are removed and replaced with the cell insulation layers 132 may be performed. That is, two replacement processes may be performed.

The opening for the separation structure may be filled with an insulating material to form the separation structure 146. The separation structure 146 may be formed by any of various processes such as deposition or so on.

Subsequently, a second wiring portion 180 (refer to FIG. 1) that is connected to the channel structure CH may be formed to form a cell region 100 (refer to FIG. 1).

According to an embodiment, the preliminary stacking portion 170p that is entirely disposed in the channel structure CH may be formed and then the partial portion of the preliminary stacking portion 170p may be removed. Thereby, the channel structure CH that includes the separated stacking portion 170 may be formed by using an easy process. In a process of removing the partial portion of the preliminary stacking portion 170p, a length of the separated stacking portion 170 may be adjusted. Accordingly, unwanted effects of the separated stacking portion 170 on adjacent memory cells may be minimized. Accordingly, a thickness of the gate electrode 130 or an interval between the gate electrodes 130 in the extension direction of the channel structure CH may be reduced. As a result, productivity, performance and reliability of the semiconductor device 10 may be enhanced.

On the other hand, in a comparative example, a penetrating portion for a channel structure is formed, and a partial portion of a sacrificial insulation layer is removed to form an expanded portion. Thereafter, a plurality layers, such as a ferroelectric layer or so on, may be formed on an inner surface of the expanded portion. It may be difficult to actually implement a manufacturing process of forming the plurality of layers, such as the ferroelectric layer or so on, to have a desired shape (for example, a layer shape that is formed continuously with a uniform thickness) in the expanded portion. For example, the expanded portion may have a sufficient thickness in an extension direction of a channel structure, considering thicknesses of the plurality of layers. Accordingly, it may be difficult to reduce a thickness of a gate electrode or an interval between the gate electrodes in the extension direction of the channel structure.

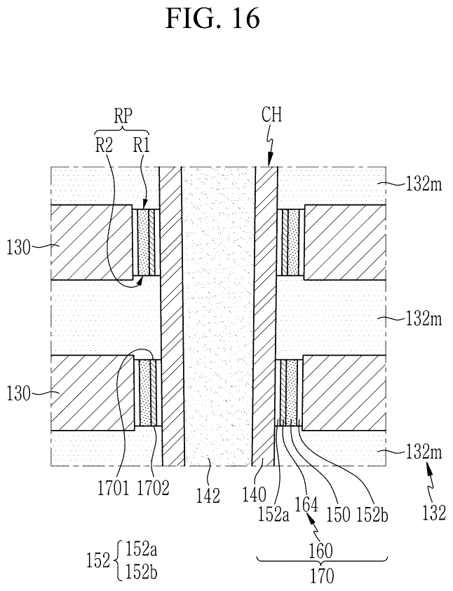

FIG. 16 is a partial cross-sectional view that illustrates a partial portion of a memory cell structure included in a semiconductor device according to an embodiment. FIG. 16 illustrates a portion that corresponds to FIG. 8.

Referring to FIG. 16, in an embodiment, an interfacial insulation layer 152 that is included in a stacking portion or a separated stacking portion 170, which is disposed between a channel layer 140 and a gate electrode 130, may include a first interfacial insulation layer 152a and a second interfacial insulation layer 152b. The first interfacial insulation layer 152a may be disposed between a conductive layer 164 and the channel layer 140. The second interfacial insulation layer 152b may be disposed between the gate electrode 130 and a ferroelectric layer 150.

In this instance, at least one of the ferroelectric layer 150, the conductive layer 164, the first interfacial insulation layer 152a, or the second interfacial insulation layer 152b may have a separated structure that is separated to correspond to each gate electrode 130. In an embodiment, at least one of the ferroelectric layer 150, the conductive layer 164, the first interfacial insulation layer 152a, or the second interfacial insulation layer 152b may correspond to a partial portion of a region (e.g., a unit region) that corresponds to each gate electrode 130. For example, at least one of the ferroelectric layer 150, the conductive layer 164, the first interfacial insulation layer 152a, or the second interfacial insulation layer 152b may have a recess portion RP, for example, a first recess portion R1 and/or a second recess portion R2.

Thereby, in an extension direction of a channel structure CH, a length of the separated stacking portion 170 that corresponds to one gate electrode 130 may be less than a thickness of one gate electrode 130. For example, in the extension direction of the channel structure CH, a length of the second interfacial insulation layer 152b that corresponds to one gate electrode 130 may be less than the thickness of one gate electrode 130.

Unless otherwise described, the description with reference to FIG. 1 to FIG. 15 may be applied to the first interfacial insulation layer 152a and the second interfacial insulation layer 152b. Unless otherwise described, embodiments and modified embodiments with reference to FIG. 1 to FIG. 15 may be applied.

In FIG. 16, it is illustrated as an example that the interfacial insulation layer 152 include the first interfacial insulation layer 152a and the second interfacial insulation layer 152b, but the embodiments are not limited thereto.

For example, the interfacial insulation layer 152 may include the second interfacial insulation layer 152b without the first interfacial insulation layer 152a.

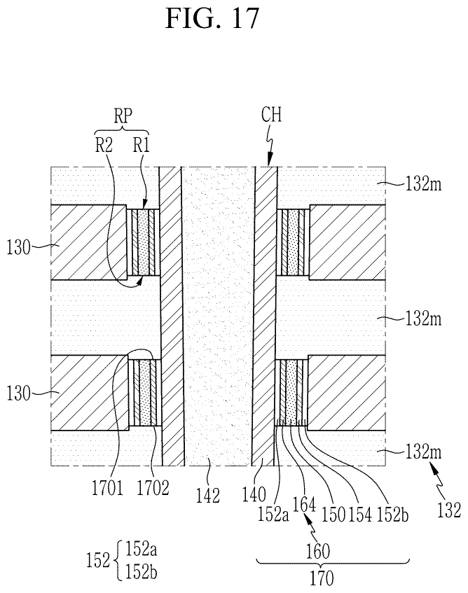

FIG. 17 is a partial cross-sectional view that illustrates a partial portion of a memory cell structure included in a semiconductor device according to an embodiment. FIG. 17 illustrates a portion that corresponds to FIG. 8.

Referring to FIG. 17, in an embodiment, an interfacial insulation layer 152 that is included in a stacking portion or a separated stacking portion 170, which is disposed between a channel layer 140 and a gate electrode 130, may include a first interfacial insulation layer 152a and a second interfacial insulation layer 152b. A channel structure CH may further include a charge trap layer 154 that is disposed between gate electrodes 130 and a ferroelectric layer 150 (more particularly, between the second interfacial insulation layer 152b and the ferroelectric layer 150).

In this instance, at least one of the ferroelectric layer 150, the conductive layer 164, the first interfacial insulation layer 152a, the second interfacial insulation layer 152b, or the charge trap layer 154 may have a separated structure that is separated to correspond to each gate electrode 130. In an embodiment, at least one of the ferroelectric layer 150, the conductive layer 164, the first interfacial insulation layer 152a, the second interfacial insulation layer 152b, or the charge trap layer 154 may correspond to a partial portion of a region (e.g., a unit region) that corresponds to each gate electrode 130. For example, at least one of the ferroelectric layer 150, the conductive layer 164, the first interfacial insulation layer 152a, the second interfacial insulation layer 152b, or the charge trap layer 154 may have a recess portion RP, for example, a first recess portion R1 and/or a second recess portion R2.

Thereby, in an extension direction of a channel structure CH, a length of the separated stacking portion 170 that corresponds to one gate electrode 130 may be less than a thickness of one gate electrode 130. For example, in the extension direction of the channel structure CH, a length of the charge trap layer 154 that corresponds to one gate electrode 130 may be less than the thickness of one gate electrode 130.

Unless otherwise described, the description with reference to FIG. 1 to FIG. 16 may be applied to the first interfacial insulation layer 152a and the second interfacial insulation layer 152b. Unless otherwise described, embodiments and modified embodiments with reference to FIG. 1 to FIG. 16 may be applied.

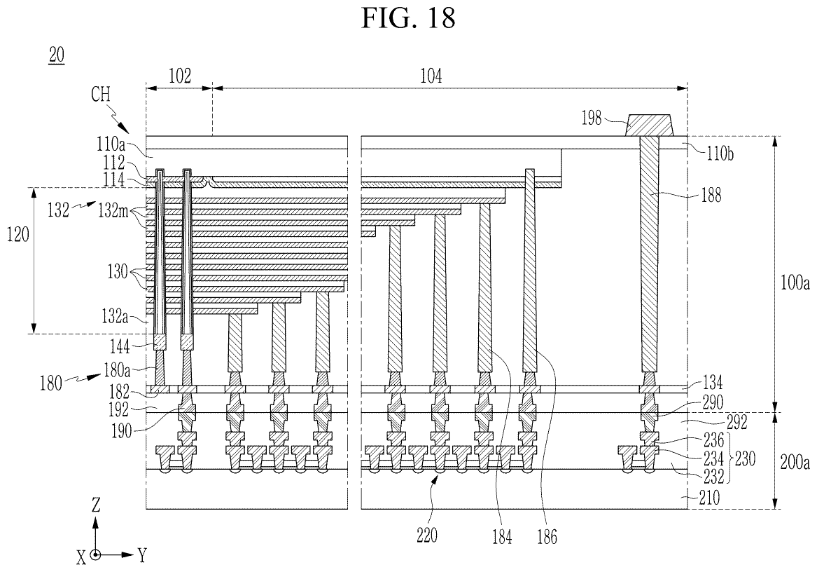

FIG. 18 is a cross-sectional view that schematically illustrates a semiconductor device 20 according to an embodiment.

Referring to FIG. 18, a semiconductor device 20 according to an embodiment may be a bonding semiconductor device that is formed by forming a cell region 100a through a process that is separately performed from a circuit region 220a and bonding the cell region 100a to the circuit region 200a. For example, the circuit region 200a and the cell region 100a may be bonded by using a hybrid bonding type. The circuit region 200a and the cell region 100a may be bonded by a chip to chip (C2C) bonding process, a chip-to-wafer bonding process, or a wafer-to-wafer bonding process.

The circuit region 200a may include a first substrate 210, a circuit element 220, a first wiring portion 230, and a first bonding structure 290 that is electrically connected to the first wiring portion 230 and is positioned at a surface facing the cell region 100a. A peripheral area of the first bonding structure 290 at the surface of the circuit region 200a may be covered by a first bonding insulation layer 292.

The cell region 100a may include a second substrate 110a, a gate stacking structure 120, a channel structure CH, a second wiring portion 180, and a second bonding structure 190 that is electrically connected to the second wiring portion 180 and is positioned at a surface facing the circuit region 200a. A peripheral area of the second bonding structure 190 may be covered by a second bonding insulation layer 192.

In an embodiment, the second substrate 110a may be a semiconductor substrate that includes a semiconductor material. For example, the second substrate 110a may be a semiconductor substrate that includes or is formed of a semiconductor material, or may be a semiconductor substrate in which a semiconductor layer is on a base substrate. For example, the second substrate 110a may include or be formed of single-crystalline or polycrystalline silicon, germanium, silicon-germanium, silicon-on-insulator, germanium-on-insulator, or so on. In some embodiments, the second substrate 110a may include a supporting member that includes an insulation layer or an insulating material. This may be because a semiconductor substrate that is provided in the cell region 100a may be removed after the cell region 100a is bonded to the circuit region 200a and the supporting member that includes the insulation layer or the insulating material may be formed.

In an embodiment, the gate stacking structure 120 may be sequentially stacked on a lower portion of the second substrate 110a in the drawing, and may have a structure in which a gate stacking structure 120 illustrated in FIG. 1 is disposed in a vertically inverted manner. A channel structure CH that passes through the gate stacking structure 120 may have a structure in which a channel structure CH illustrated in FIG. 2 is disposed in a vertically inverted manner. Accordingly, in a cross-sectional view, the channel structure CH may have an inclined side surface such that a width of the channel structure CH decreases from the circuit region 200a toward the second substrate 110a. A channel pad 144 and the second wiring portion 180 that are disposed at an upper portion of the gate stacking structure 120 may be adjacent to the circuit region 200a.

In an embodiment, an input/output connection wiring 188 may be electrically connected to a part of second bonding structures 190. For example, an input/output pad 198 may be disposed on an outer insulation layer 110b that is disposed on an outer surface of the second substrate 110a. In some embodiments, an additional input/output pad that is electrically connected to the circuit region 200a may be provided. In some embodiment, an insulation layer that covers a partial portion of the input/output pad 198 may be further included.

In FIG. 18, it is illustrated as an example that the gate stacking structure 120 includes one stacking portion. In some embodiment, the gate stacking structure 120 may include two or more gate stacking portions. Unless otherwise described, the description of a gate stacking structure 120 and a channel structure CH with reference to FIG. 1 and FIG. 2 may be applied as is. In FIG. 18, it is illustrated as an example that an electrical connection structure of the channel structure CH with horizontal conductive layers 112 and 114 and/or the second substrate 110a is the same as an electrical connection structure of a channel structure CH with horizontal conductive layers 112 and 114 and/or a second substrate 110 in FIG. 1. The embodiments are not limited thereto, and the electrical connection structure of the channel structure CH with the horizontal conductive layers 112 and 114 and/or the second substrate 110a may be variously modified.

The circuit region 200a and the cell region 100a may be bonded by hybrid bonding. More particularly, the circuit region 200a and the cell region 100a may be bonded by the hybrid bonding including metal bonding between the first bonding structure 290 and the second bonding structure 190 and insulation-layer bonding between the first bonding insulation layer 292 and the second bonding insulation layer 192.

For example, the first boding structure 290 and/or the second bonding structure 190 may include at least one of copper, aluminum, tungsten, nickel, gold, tin, manganese, cobalt, titanium, tantalum, ruthenium, or beryllium, or an alloy including the same. For example, the first and second bonding structures 290 and 190 may include copper so that the cell region 100a and the circuit region 200a may be bonded (e.g., directly bonded) to each other by copper-to-copper bonding.

For example, at an insulation-layer bonding surface, the first bonding insulation layer 292 and the second bonding insulation layer 192 may include the same insulating material. For example, the first bonding insulation layer 292 and/or the second bonding insulation layer 192 may include a layer that includes silicon carbonitride at least at the bonding surface. However, the embodiments are not limited thereto. The first boding insulation layer 292 and/or the second bonding insulation layer 192 may include a material that is the same as or a different from the cell insulation layer 132 or an additional insulation layer 134 of the cell region 100a or an insulation layer 232 of the circuit region 200a.

In an embodiment, by the second wiring portion 180, the second bonding structure 190, the first bonding structure 290, and the first wiring portion 230, a bit line 182 that is connected to the channel structure CH, a gate electrode 130, the second substrate 110a, and/or the horizontal conductive layers 112 and 114 may be electrically connected to the circuit element 220 of the circuit region 200a.

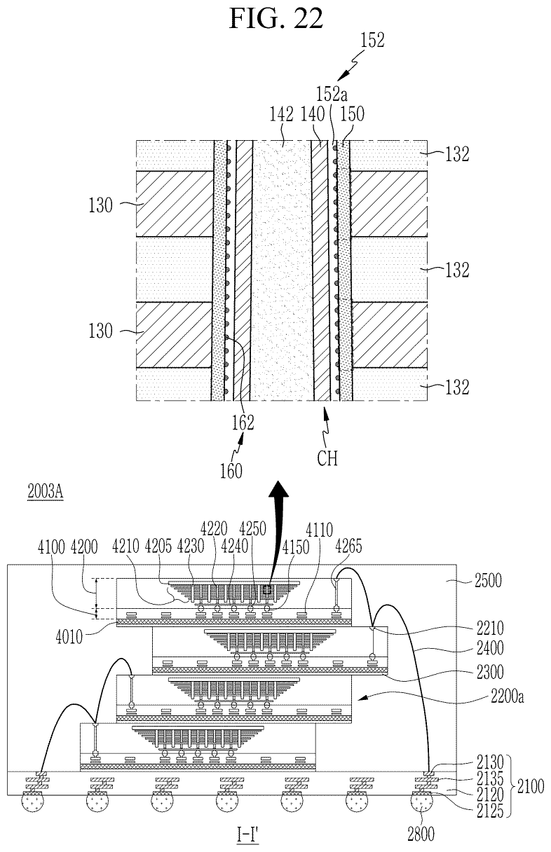

For example, the circuit region 200a and the cell region 100a may correspond to a first structure 1100F and a second structure 1100S of a semiconductor device 1100 that is included in an electronic system 1000 illustrated in FIG. 19, respectively. For example, the circuit region 200a and the cell region 100a may be regions that include a first structure 4100 and a second structure 4200 of a semiconductor chip 2200a illustrated in FIG. 22, respectively.

Hereinafter, an example of an electronic system that includes a semiconductor device described in the above will be described in detail.

FIG. 19 schematically illustrates an electronic system that includes a semiconductor device according to an embodiment.

Referring to FIG. 19, an electronic system 1000 according to an embodiment may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 18. The semiconductor device 1100 may include a first structure 1100F and a second structure 1100S that is disposed on the first structure 1100F. In some embodiments, the first structure 1100F may be next to the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to an embodiment.

In an embodiment, the lower transistor LT1 or LT2 may include a ground selection transistor, and the upper transistor UT1 or UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or so on may be transmitted through the NAND interface 1221. The host interface 1230 may provide a communication function between the electronic system 1000 and an external host.

When a control command is received from the external host through the host interface 1230, the processor 1210 may control the semiconductor device 1100 in response to the control command.

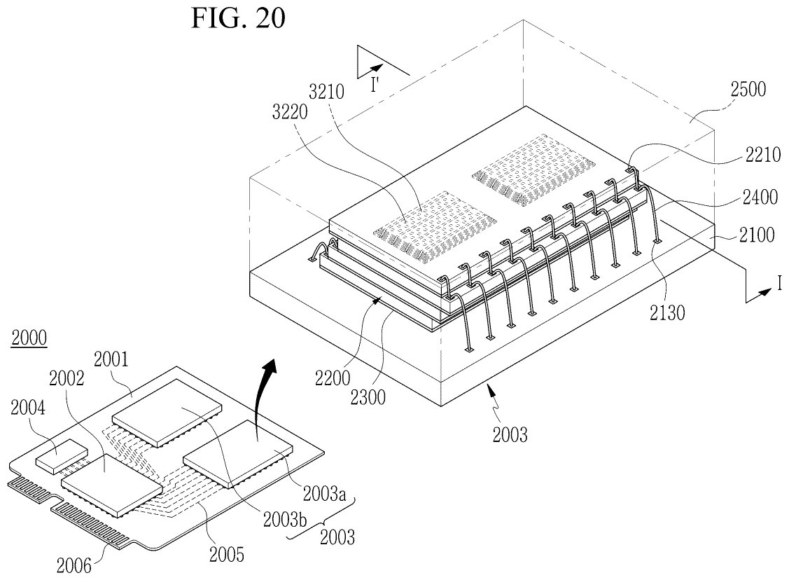

FIG. 20 is a perspective view that schematically illustrates an electronic system including a semiconductor device according to an embodiment.

Referring to FIG. 20, an electronic system 2000 according to an embodiment may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In an embodiment, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package that includes a plurality of semiconductor chips 2200. Each of the first and second semiconductor packages 2003a and 2003b may include a package substrate 2100, the semiconductor chip 2200 that is disposed on the package substrate 2100, an adhesive layer 2300 at a lower surface of each semiconductor chip 2200, a connection structure 2400 that electrically connect the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 19. Each semiconductor chip 2200 may include a gate stacking structure 3210 and a channel structure 3220. The semiconductor chip 2200 may include the semiconductor device described with reference to FIG. 1 to FIG. 18.

In an embodiment, the connection structure 2400 may be a bonding wire that electrically connects the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to the package upper pad 2130 of the package substrate 2100. According to an embodiment, in each of the first and second semiconductor packages 2003a and 2003b, the semiconductor chips 2200 may be electrically connected to each other by a connection structure that includes a through silicon via (TSV) instead of the connection structure 2400 of the bonding wire type.

In an embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring of the interposer substrate.

FIG. 21 and FIG. 22 are cross-sectional views schematically illustrating semiconductor packages according to embodiments, respectively. FIG. 21 and FIG. 22 respectively illustrate embodiments of the semiconductor package 2003 of FIG. 16, and conceptually illustrate a region of the semiconductor package 2003 taken along a line I-I′ in FIG. 20.

Referring to FIG. 21, in a semiconductor package 2003, a package substrate 2100 may be a printed circuit board. The package substrate 2100 may include a package substrate body portion 2120, a package upper pad 2130 that is disposed at an upper surface of the package substrate body portion 2120, a package lower pad 2125 that is disposed at a lower surface of the package substrate body portion 2120 or is exposed through the lower surface of the package substrate body portion 2120, and an internal wiring 2135 that electrically connects the package upper pad 2130 and the package lower pad 2125 inside the package substrate body portion 2120. The package upper pad 2130 may be electrically connected to the connection structure 2400. The package lower pad 2125 may be connected to a wiring pattern 2005 of a main substrate 2001 of an electronic system 2000, as illustrated in FIG. 20, through a conductive connection portion 2800.

The semiconductor chip 2200 may include a semiconductor substrate 3010, and a first structure 3100 and a second structure 3200 that are sequentially stacked on the semiconductor substrate 3010. The first structure 3100 may include a peripheral circuit region that includes a peripheral wiring 3110. The second structure 3200 may include a common source line 3205, a gate stacking structure 3210 that is disposed on the common source line 3205, a channel structure 3220 and a separation structure 3230 that pass through the gate stacking structure 3210, a bit line 3240 that is electrically connected to the channel structure 3220, and a gate connection wiring that is electrically connected to a word line WL (refer to FIG. 19) of the gate stacking structure 3210.

In a semiconductor chip 2200 or a semiconductor device, depolarization may be suppressed by a conductive pattern that is adjacent to an inner surface of a ferroelectric layer, and thus, performance and reliability of the semiconductor chip 2200 or the semiconductor device may be enhanced.

Each of the semiconductor chips 2200 may include a through wiring 3245 that is electrically connected to the peripheral wiring 3110 of the first structure 3100 and extends into the second structure 3200. The through wiring 3245 may pass through the gate stacking structure 3210, and may be further provided at an outside of the gate stacking structure 3210. Each semiconductor chip 2200 may further include an input/output connection wiring 3265 that is electrically connected to the peripheral wiring 3110 of the first structure 3100 and extend into the second structure 3200, and an input/output pad 2210 that is electrically connected to the input/output connection wiring 3265.

In an embodiment, in the semiconductor package 2003, a plurality of semiconductor chips 2200 may be electrically connected to each other by a connection structure 2400 having a bonding wire type. In some embodiments, the plurality of semiconductor chips 2200 or a plurality of portions that constitute the plurality of semiconductor chips 2200 may be electrically connected by a connection structure that includes a through silicon via (TSV).

Referring to FIG. 22, in a semiconductor package 2003A, each semiconductor chip 2200a may include a semiconductor substrate 4010, a first structure 4100 that is disposed on the semiconductor substrate 4010, and a second structure 4200 that is disposed on the first structure 4100 and is bonded to the first structure 4100 by a wafer bonding type.

The first structure 4100 may include a peripheral circuit region that includes a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 that pass through the gate stacking structure 4210, and a second bonding structures 4250 that are electrically connected to the channel structure 4220 and a word line WL (refer to FIG. 19) of the gate stacking structure 4210. For example, the second bonding structure 4250 may be electrically connected to the channel structure 4220 and the word line WL through a bit line 4240 that is electrically connected to the channel structure 4220 and a gate connection wiring that is electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In a semiconductor chip 2200a or a semiconductor device, depolarization may be suppressed by a conductive pattern that is adjacent to an inner surface of a ferroelectric layer, and thus, performance and reliability of the semiconductor chip 2200a or the semiconductor device may be enhanced.

Each of the semiconductor chips 2200a may further include an input/output pad 2210 and an input/output connection wiring 4265 that is disposed at a lower portion of the input/output pad 2210. The input/output connection wiring 4265 may be electrically connected to a part of the second bonding structures 4250.

In an embodiment, in the semiconductor package 2003A, a plurality of semiconductor chips 2200a may be electrically connected to each other by a connection structure 2400 having a bonding wire type. In some embodiments, the plurality of semiconductor chips 2200a or a plurality of portions that constitute the plurality of semiconductor chips 2200a may be electrically connected by a connection structure that includes a through silicon via (TSV).

The above-described semiconductor device, electronic system, or semiconductor package according to embodiments may be included in various electronic products including display devices, televisions, computers (e.g., laptops), phones (e.g., smartphones), severs, infotainment systems, or the like.

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. A semiconductor device, comprising:
a gate stacking structure that includes a plurality of gate electrodes and a plurality of cell insulation layers alternately stacked with each other;
a channel layer extending in an extension direction to pass through the gate stacking structure;
a ferroelectric layer; and
a conductive structure disposed between the ferroelectric layer and the channel layer to partially overlap one of the plurality of gate electrodes in a direction perpendicular to the extension direction.

2. The semiconductor device of claim 1, wherein the conductive structure includes a plurality of nanocrystals spaced apart from each other.

3. The semiconductor device of claim 2, wherein the plurality of nanocrystals are spaced apart from each other in the extension direction and in a plan view.

4. The semiconductor device of claim 2, wherein the plurality of nanocrystals include first nanocrystals overlapping the one of the plurality of gate electrodes in the direction perpendicular to the extension direction and second nanocrystals overlapping one of the plurality of cell insulation layers in the direction perpendicular to the extension direction.

5. The semiconductor device of claim 2, wherein one or more of the plurality of nanocrystals are embedded in an interfacial insulation layer disposed between the one of the plurality of gate electrodes and the channel layer; or
one or more of the plurality of nanocrystals are in contact with the ferroelectric layer; or
wherein at least one of the ferroelectric layer or the channel layer has an extended structure that extends in the extension direction to correspond to the plurality of gate electrodes.

6. The semiconductor device of claim 1, wherein the conductive structure includes a conductive layer of a layer shape extending in the extension direction.

7. The semiconductor device of claim 6, wherein, in the extension direction, a length of the conductive layer that corresponds to the one of the plurality of gate electrodes is less than a thickness of the one of the plurality of gate electrodes.

8. The semiconductor device of claim 6, wherein the conductive layer has a recess portion disposed inside the one of the plurality of gate electrodes in the extension direction.

9. The semiconductor device of claim 1, comprising:
a plurality of separated stacking portions that are disposed between the channel layer and the plurality of gate electrodes, respectively,
at least one of the plurality of separated stacking portions includes the ferroelectric layer and the conductive structure, and
the plurality of separated stacking portions have a separated structure that is separated to correspond to the plurality of gate electrodes, respectively.

10. The semiconductor device of claim 9, wherein the at least one of the plurality of separated stacking portions includes at least a portion that has a length less than a thickness of the one of the plurality of gate electrodes in the extension direction.

11. The semiconductor device of claim 9, wherein the at least one of the plurality of separated stacking portions has a recess portion disposed inside the one of the plurality of gate electrodes in the extension direction.

12. The semiconductor device of claim 9, wherein at least one of the plurality of cell insulation layers includes a first insulation portion and a second insulation portion,
the first insulation portion is disposed between the plurality of gate electrodes, and
the second insulation portion is disposed between the plurality of separated stacking portions and protrudes than the first insulation portion.

13. The semiconductor device of claim 9, wherein a surface of the at least one of the plurality of separated stacking portions that crosses the extension direction includes an inclined surface so that a length of the at least one of the plurality of separated stacking portions in the extension direction increases from a portion that is close to the plurality of gate electrodes to another portion that is close to the channel layer.

14. The semiconductor device of claim 1, wherein the conductive structure includes a semiconductor material or a metal.

15. The semiconductor device of claim 1, wherein a thickness of the conductive structure is less than a thickness of the ferroelectric layer or a thickness of the channel layer.

16. A semiconductor device, comprising:
a gate stacking structure that includes a plurality of gate electrodes and a plurality of cell insulation layers alternately stacked with each other; and
a channel structure that extends to pass through the gate stacking structure,
wherein the channel structure includes a channel layer and a plurality of separated stacking portions that are disposed between the channel layer and the plurality of gate electrodes, respectively,
at least one of the plurality of separated stacking portions includes a ferroelectric layer and a conductive structure,
the plurality of separated stacking portions have a separated structure that is separated to correspond to the plurality of gate electrodes, respectively, and
the at least one of the plurality of separated stacking portions has a recess portion disposed inside one of the plurality of gate electrodes in an extension direction of the channel structure.

17. The semiconductor device of claim 16, wherein the at least one of the plurality of separated stacking portions includes at least a portion that has a length less than a thickness of the one of the plurality of gate electrodes in the extension direction of the channel structure.

18. The semiconductor device of claim 16, wherein the at least one of the plurality of separated stacking portions includes at least one of a first interfacial insulation layer that is disposed between the ferroelectric layer and the channel layer, a second interfacial insulation layer that is disposed between the plurality of gate electrodes and the ferroelectric layer, or a charge trap layer that is disposed between the plurality of gate electrodes and the ferroelectric layer.

19. The semiconductor device of claim 16, wherein at least one of the plurality of cell insulation layers includes a first insulation portion and a second insulation portion,
the first insulation portion is disposed between the plurality of gate electrodes, and
the second insulation portion is disposed between the plurality of separated stacking portions and protrudes than the first insulation portion.

20. An electronic system, comprising:
a main substrate;
a semiconductor device on the main substrate; and
a controller that is disposed on the main substrate and is electrically connected to the semiconductor device,
wherein the semiconductor device includes:
a gate stacking structure that includes a plurality of gate electrodes and a plurality of cell insulation layers alternately stacked with each other;
a channel layer extending in an extension direction to pass through the gate stacking structure;
a ferroelectric layer; and
a conductive structure disposed between the ferroelectric layer and the channel layer to partially overlap one of the plurality of gate electrodes in a direction perpendicular to the extension direction.
